(19) United States
(12) Patent Application Publication
(10) Pub. No.: US 2018/0090658 A1
(43) Pub. Date: Mar. 29, 2018

(54) THERMOELECTRIC CONVERSION DEVICE

(71) Applicant: KABUSHIKI KAISHA TOSHIBA, Tokyo (JP)

(72) Inventors: Yusuke KASAHARA, Yokohama Kanagawa (JP); Miwa SATO, Ota Tokyo (JP); Yasuo AKATSUKA, Shinjuku Tokyo (JP); Masamichi SUZUKI, Koto Tokyo (JP); Tomoaki INOKUCHI, Yokohama Kanagawa (JP)

(21) Appl. No.: 15/448,475

(22) Filed: Mar. 2, 2017

(30) Foreign Application Priority Data
Sep. 26, 2016 (JP) 2016-186721

(51) Int. Cl. H01L 35/32; H01L 35/34; H01L 35/10

(52) U.S. Cl. CPC H01L 35/325; H01L 35/10; H01L 35/34

(57) ABSTRACT

According to one embodiment, a thermoelectric conversion device includes a first stacked body comprising a plurality of first semiconductor layers of a first conductivity type, the first semiconductor layers spaced from each other in a first direction, a second stacked body comprising a plurality of second semiconductor layers of a second conductivity type, the second semiconductor layers spaced from each other in the first direction, and a first connection portion electrically connecting the first stacked body to the second stacked body, wherein the first stacked body has a plurality of first openings that extend inwardly of the first stacked body in the first direction, wherein a direction from the first stacked body to the second stacked body intersects the first direction, and wherein the second stacked body has a plurality of second openings extending inwardly of the second stacked body in the first direction.

### CROSS-REFERENCE TO RELATED APPLICATION

This application is based upon and claims the benefit of priority from Japanese Patent Application No. 2016-186721, filed Sep. 26, 2016, the entire contents of which are incorporated herein by reference.

### FIELD

Embodiments described herein relate generally to a thermoelectric conversion device.

### BACKGROUND

Thermoelectric conversion devices that use semiconductors are known. There is a demand for improvement in conversion efficiency in the thermoelectric conversion device.

### DESCRIPTION OF THE DRAWINGS

FIGS. 1A and 1B are schematic perspective views illustrating a thermoelectric conversion device according to a first embodiment.

FIGS. 2A to 2D are schematic sectional views illustrating the thermoelectric conversion device according to the first embodiment.

FIGS. 3A and 3B are schematic views illustrating aspects of a method of manufacturing the thermoelectric conversion device according to the first embodiment.

FIGS. 4A and 4B are schematic views illustrating aspects of a method of manufacturing the thermoelectric conversion device according to the first embodiment.

FIGS. 5A and 5B are schematic views illustrating aspects of a method of manufacturing the thermoelectric conversion device according to the first embodiment.

FIGS. 6A and 6B are schematic views illustrating aspects of a method of manufacturing the thermoelectric conversion device according to the first embodiment.

FIGS. 7A and 7B are schematic views illustrating aspects of a method of manufacturing the thermoelectric conversion device according to the first embodiment.

FIG. 8 is a schematic sectional view illustrating another thermoelectric conversion device according to the first embodiment.

FIGS. 9A and 9B are schematic perspective views illustrating a thermoelectric conversion device according to a second embodiment.

FIGS. 10A to 10C are schematic sectional views illustrating the thermoelectric conversion device according to the second embodiment.

FIGS. 11A and 11B are schematic views illustrating another thermoelectric conversion device according to the second embodiment.

FIGS. 12A to 12C are schematic sectional views illustrating another thermoelectric conversion device according to the second embodiment.

FIGS. 13A to 13F are schematic sectional views illustrating aspects of a method of manufacturing the thermoelectric conversion device according to the second embodiment.

FIGS. 14A to 14F are schematic sectional views illustrating aspects of a method of manufacturing the thermoelectric conversion device according to the second embodiment.

FIGS. 15A to 15F are schematic sectional views illustrating aspects of a method of manufacturing the thermoelectric conversion device according to the second embodiment.

FIGS. 16A to 16F are schematic sectional views illustrating aspects of a method of manufacturing the thermoelectric conversion device according to the second embodiment.

FIGS. 17A to 17F are schematic sectional views illustrating aspects of a method of manufacturing the thermoelectric conversion device according to the second embodiment.

FIG. 18 is a schematic plan view illustrating another thermoelectric conversion device according to the second embodiment.

FIGS. 19A and 19B are schematic perspective views illustrating a thermoelectric conversion device according to a third embodiment.

FIGS. 20A and 20B are schematic sectional views illustrating the thermoelectric conversion device according to the third embodiment.

FIGS. 21A to 21D are schematic sectional views illustrating the thermoelectric conversion device according to the third embodiment.

FIGS. 22A and 22B are schematic views illustrating a thermoelectric conversion device according to a fourth embodiment.

FIGS. 23A to 23C are schematic sectional views illustrating the thermoelectric conversion device according to the fourth embodiment.

FIGS. 24A to 24D are schematic views illustrating another thermoelectric conversion device according to the fourth embodiment.

FIGS. 25A and 25B are schematic views illustrating another thermoelectric conversion device according to the fourth embodiment.

FIGS. 26A and 26B are schematic sectional views illustrating a thermoelectric conversion device according to a fifth embodiment.

FIGS. 27A to 27H are schematic views illustrating aspects of a method of manufacturing the thermoelectric conversion device according to the fifth embodiment.

FIGS. 28A to 28J are schematic views illustrating aspects of a method of manufacturing the thermoelectric conversion device according to the fifth embodiment.

FIGS. 29A to 29J are schematic views illustrating aspects of a method of manufacturing the thermoelectric conversion device according to the fifth embodiment.

FIGS. 30A to 30C are schematic views illustrating a thermoelectric conversion device according to a sixth embodiment.

FIGS. 31A and 31B are schematic views illustrating the thermoelectric conversion device according to the sixth embodiment.

FIGS. 32A and 32B are schematic views illustrating the thermoelectric conversion device according to the sixth embodiment.

FIGS. 33A to 33D are schematic sectional views, illustrating aspects of a method of manufacturing the thermoelectric conversion device according to the sixth embodiment.

FIGS. 34A to 34D are schematic sectional views illustrating aspects of in a method of manufacturing the thermoelectric conversion device according to the sixth embodiment.

FIGS. 35A to 35C are schematic sectional views, illustrating a result of steps in a method of manufacturing the thermoelectric conversion device according to the sixth embodiment.

FIGS. 36A to 36C are schematic views illustrating another thermoelectric conversion device according to the sixth embodiment.

FIGS. 37A to 37C are schematic views illustrating another thermoelectric conversion device according to the sixth embodiment.

FIGS. 38A and 38B are schematic views illustrating another thermoelectric conversion device according to the sixth embodiment.

FIGS. 39A and 39B are schematic views illustrating another thermoelectric conversion device according to the sixth embodiment.

FIGS. 40A to 40D are schematic sectional views, illustrating aspects of another method of manufacturing the thermoelectric conversion device according to the sixth embodiment.

FIGS. 41A to 41D are schematic sectional views, illustrating aspects of another method of manufacturing the thermoelectric conversion device according to the sixth embodiment.

FIGS. 42A to 42D are schematic sectional views, illustrating aspects of another method of manufacturing the thermoelectric conversion device according to the sixth embodiment.

FIGS. 43A to 43D are schematic sectional views, illustrating aspects of another method of manufacturing the thermoelectric conversion device according to the sixth embodiment.

FIGS. 44A to 44B are schematic sectional views illustrating aspects of another method of manufacturing the thermoelectric conversion device according to the sixth embodiment.

FIG. 45 is a schematic sectional view, illustrating aspects of another method of manufacturing the thermoelectric conversion device according to the sixth embodiment.

FIGS. 46A to 46D are schematic perspective views illustrating the thermoelectric conversion device according to an embodiment.

FIG. 47 is a schematic perspective view illustrating a thermoelectric conversion module according to an embodiment.

### DETAILED DESCRIPTION

Example embodiments provide a thermoelectric conversion device that can improve an output per unit area.

In general, according to one embodiment, a thermoelectric conversion device includes a first stacked body comprising a plurality of first semiconductor layers of a first conductivity type, the first semiconductor layers spaced from each other in a first direction, a second stacked body comprising a plurality of second semiconductor layers of a second conductivity type, the second semiconductor layers spaced from each other in the first direction, and a first connection portion electrically connecting the first stacked body to the second stacked body, wherein the first stacked body has a plurality of first openings that extend inwardly of the first stacked body in the first direction, wherein a direction from the first stacked body to the second stacked body intersects the first direction, and wherein the second stacked body has a plurality of second openings extending inwardly of the second stacked body in the first direction.

Each embodiment will be described below with reference to the drawings.

The drawings are schematic and conceptual. For example, the relationship between the thickness and width of each component and a ratio in size between components are not necessarily the same as those of an actual device. In some cases, even the same components are shown having different dimensions or different relative sizes in the drawings.

In the present specification and drawings, the same constituent element as described with reference to a previous drawing is given the same reference numeral, and a detailed description thereof is suitably omitted.

### First Embodiment

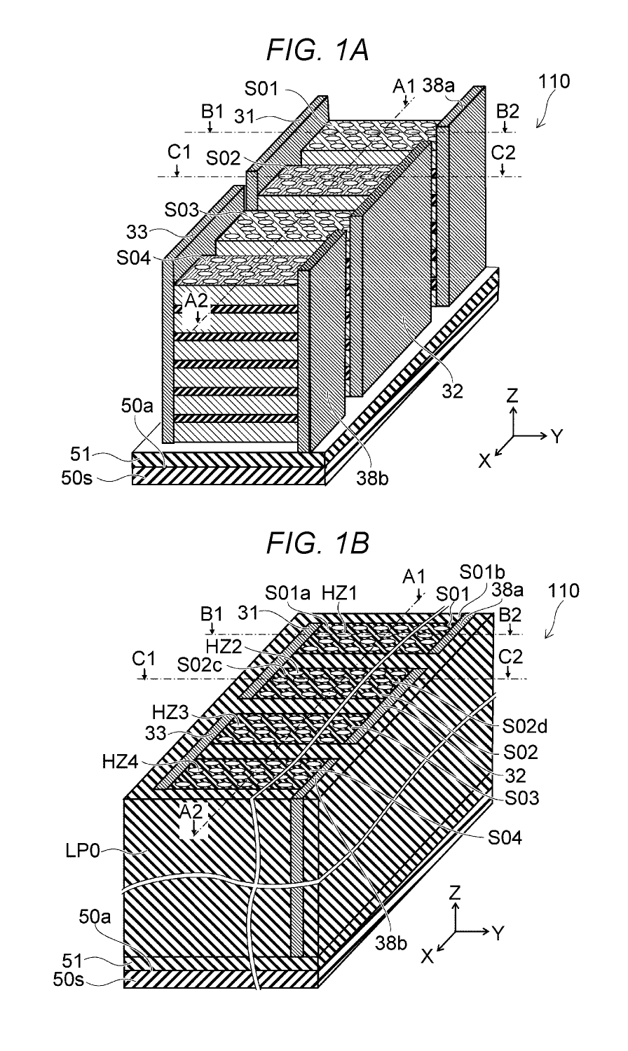

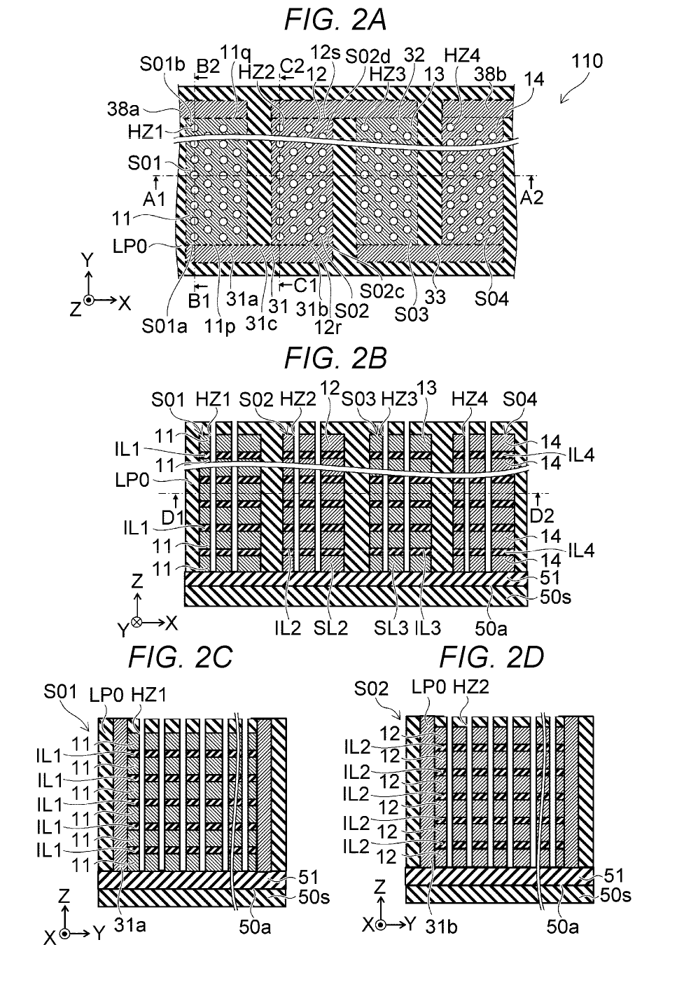

FIG. 1A, FIG. 1B, and FIGS. 2A to 2D are schematic views illustrating a thermoelectric conversion device according to a first embodiment.

FIGS. 1A and 1B are perspective views of a thermoelectric conversion device. In FIG. 1A, some constituent elements of the device are omitted. FIG. 2A is a sectional view taken along line D1-D2 in FIG. 2B. FIG. 2B is a sectional view taken along line A1-A2 in FIGS. 1A and 1B and FIG. 2A. FIG. 2C is a sectional view taken along line B1-B2 in FIGS. 1A and 1B, and FIG. 2A. FIG. 2D is a sectional view taken along line C1-C2 in FIGS. 1A and 1B and FIG. 2A.

As illustrated in these figures, the thermoelectric conversion device 110 according to the present embodiment includes a first stacked body S01, a second stacked body S02, and a first connection portion 31.

The first stacked body S01 includes a plurality of first semiconductor layers 11. The plurality of first semiconductor layers 11 spaced apart from each other in a first direction.

Herein, the first direction is defined as a Z-axis direction. One direction that is perpendicular to the Z-axis direction is defined as an X-axis direction. A direction that is perpendicular to the Z-axis direction and the X-axis direction is defined as a Y-axis direction.

The plurality of first semiconductor layers 11 are spaced from each other in the first direction (the Z-axis direction). The plurality of first semiconductor layers 11 are of a first conductivity type.

The first stacked body S01 has a plurality of first holes HZ1 extending thereinto. The plurality of first holes HZ1 extend through the plurality of first semiconductor layers 11 in the first direction, and thus extend in the first stacked body S01 in the first direction.

The direction from the first stacked body S01 to the second stacked body S02 intersects the first direction. In this example, the direction from the first stacked body S01 to the second stacked body S02 is the X-axis direction. For example, the direction from the first stacked body S01 to the second stacked body S02 is substantially parallel to the X-axis direction. The second stacked body S02 includes a plurality of second semiconductor layers 12. The plurality of second semiconductor layers 12 are spaced from each other in the first direction. The plurality of second semiconductor layers 12 are of a second conductivity type different than the first conductivity type.

The second stacked body S02 has a plurality of second holes HZ2. The plurality of second holes HZ2 extend through the plurality of second semiconductor layers 12 in the first direction, and thus extend in the second stacked body S02 in the first direction.

The first connection portion 31 electrically connects at least one of the plurality of first semiconductor layers 11 and at least one of the plurality of second semiconductor layers 12 to each other. In this example, the first connection portion 31 connects the plurality of first semiconductor layers 11 and the plurality of second semiconductor layers 12 to each other.

For example, herein the first conductivity type is an n type, and the second conductivity type is a p type. However, according to the embodiment, the first conductivity type may be the p type, and the second conductivity type may be the n type. In the following description, the first conductivity type is the n type and the second conductivity type is the p type.

The plurality of semiconductor layers (the plurality of first semiconductor layers 11 and the plurality of second semiconductor layers 12), for example, contain silicon. The plurality of semiconductor layers, for example, contain polysilicon. The plurality of semiconductor layers, for example, contain germanium. The plurality of semiconductor layers may contain Bi and Te.

In this example, a base body 50s is provided. A plurality of stacked bodies (the first stacked body S01 and the second stacked body S02) are provided on a surface 50a of the base body 50s. The first direction (the Z-axis direction) described above intersects the surface 50a. For example, the first direction is substantially perpendicular to the surface 50a. The base body 50s may contain at least any one of glass, metal, and ceramic.

In this example, an insulating layer 51 and an insulating portion LP0 are provided. The insulating layer 51 is provided between the base body 50s and the plurality of stacked bodies thereon. The insulating layer 51, for example, electrically insulates the base body 50s and the plurality of stacked bodies from each other. The insulating portion LP0 surrounds at least one or several of the plurality of stacked bodies.

The base body 50s, for example, is a substrate (for example, a silicon substrate or the like). The base body 50s may include at least one or several portions of a semiconductor substrate. The insulating layer 51 and the insulating portion LP0 contain silicon oxide.

As illustrated in FIG. 1B, the first stacked body S01, for example, has a first portion S01a and a second portion S01b. The first portion S01a is a first connection portion 31 side portion. The second portion S01b is a portion of the first stacked body S01 on the opposite side thereof from the first portion S01a. The second stacked body S02, for example, has a third portion S02c and a fourth portion S02d. The third portion S02c is on the first connection portion 31 side of the second stacked body S02. The fourth portion S02d is a portion of the second stacked body S02 on the opposite side thereof from the third portion S02c. As will be described below, a temperature difference is provided between each of these portions.

For example, a side of the thermoelectric conversion device 110 is brought into contact with, or close to, a heat source. Accordingly, for example, a temperature difference occurs between the first portion S01a and the second portion S01b of the first stacked body S01. In the same manner, the temperature difference occurs between the third portion S02c and the fourth portion S02d of the second stacked body S02. For example, the temperature of each of the first portion S01a and the third portion S02c is higher than the temperature of each of the second portion S01b and the fourth portion S02d.

In this configuration, a current flows between a high temperature portion and a low temperature portion. This, for example, is based on the Seebeck effect. For example, when a load is connected to the thermoelectric conversion device 110, current flows from the device. In this manner, in the thermoelectric conversion device 110, heat is converted into electric power. In the thermoelectric conversion device 110, for example, the temperature difference is converted into electric power.

According to the embodiment, in the first stacked body S01, the plurality of first semiconductor layers 11 are stacked on top of one another, and in the second stacked body S02, the plurality of second semiconductor layers 12 are stacked on top of one another. Accordingly, the current (an electric power) that flows out per unit area is large.

Additionally, in the first stacked body S01, the plurality of first holes HZ1 are provided, and in the second stacked body S02, the plurality of second holes HZ2 are provided.

As illustrated in FIGS. 2B and 2C, each of the plurality of first holes HZ1 extend in the first stacked body S01 in the first direction (the Z-axis direction). For example, with respect to any one of the plurality of first holes HZ1, a position (a position within a X-Y plane) of one hole in one of the plurality of first semiconductor layers 11 is substantially the same as a position of one hole in another one of the plurality of first semiconductor layers 11. In this manner, the plurality of first holes HZ1 are continuous in the plurality of first semiconductor layers 11.

As illustrated in FIGS. 2B and 2D, each of the plurality of second holes HZ2 extends in the second stacked body S02 along the first direction (the Z-axis direction). The plurality of second holes HZ2 are continuous in the plurality of second semiconductor layers 12.

In this manner, according to the embodiment, a plurality of holes that extend in the first direction are provided. Accordingly, for example, an effective heat resistance in the direction between the high temperature portion and the low temperature portion can be increased in each of the plurality of semiconductor layers. For example, reduction in the temperature difference resulting from heat conduction can be suppressed. Thus, a great temperature difference is easy to maintain. In the conversion of the heat (for example, the temperature difference) into the electric power, high efficiency can be obtained.

As already described, according to the embodiment, each of the plurality of holes is continuous in the Z-axis direction (a stacking direction) into the stacked body. For example, the number of holes, or the hole pitch in the x-y plane, is the same in the plurality of semiconductor layers. For this reason, for example, non-uniformity in thermoelectric properties among the plurality of semiconductor layers is suppressed. Since each of the plurality of holes is continuous in the stacking direction, for example, it is possible to manufacture a structure (which will be described below) in which a recess portion or a cavity is provided on or in the base body 50s, and it is easy to improve power output.

Integration is possible by employing a structure in which thermoelectric elements are stacked on top of one another and the electric power (at least any one of the current and the voltage) that is obtained per unit area can thus be increased. The great temperature difference is easy to maintain. According to the embodiment, a thermoelectric conversion device that can improve an output per unit area can be provided.

In this example, a third stacked body S03, a fourth stacked body S04, a second connection portion 32, and a third connection portion 33 are provided in the thermoelectric conversion device 110.

In this example, the direction from the second stacked body S02 to the third stacked body S03 is the X-axis direction. The third stacked body S03 includes a plurality of third semiconductor layers 13. The plurality of third semiconductor layers 13 are the first conductivity type. The third stacked body S03 has a plurality of third holes HZ3. The plurality of third holes HZ3 extend through the plurality of third semiconductor layers 13 in the first direction. The plurality of third holes HZ3 thus extend in the third stacked body S03 in the first direction.

The direction from the third stacked body S03 to the fourth stacked body S04 intersects the first direction (the Z-axis direction). In this example, the direction from the third stacked body S03 to the fourth stacked body S04 is the X-axis direction. The fourth stacked body S04 includes a plurality of fourth semiconductor layers 14. The plurality of fourth semiconductor layers 14 are the second conductivity type. The fourth stacked body S04 has a plurality of fourth holes HZ4. The plurality of fourth holes HZ4 extend through the plurality of fourth semiconductor layers 14 in the first direction. The plurality of fourth holes HZ4 thus extend in the fourth stacked body S04 in the first direction.

The second connection portion 32 electrically connects at least one of the plurality of second semiconductor layers 12 and at least one of the plurality of third semiconductor layers 13 to each other. In this example, the second connection portion 32 electrically connects the plurality of second semiconductor layers 12 and the plurality of third semiconductor layer 13 to each other.

The third connection portion 33 electrically connects at least one of the plurality of third semiconductor layers 13 and at least one of the plurality of fourth semiconductor layers 14 to each other. In this example, the third connection portion 33 electrically connects the plurality of third semiconductor layers 13 and the plurality of fourth semiconductor layer 14 to each other.

In this example, the thermoelectric conversion device 110 further includes a first terminal 38a and a second terminal 38b. The first terminal 38a is electrically connected to the plurality of first semiconductor layers 11. The second terminal 38b is electrically connected to the plurality of fourth semiconductor layers 14. A current (an electric power) flows from these terminals when they are connected across a load.

In this manner, in the thermoelectric conversion device 110, the plurality of stacked bodies are provided. Each of the plurality of stacked bodies includes the plurality of semiconductor layers and has the plurality of holes. The number of the plurality of stacked bodies is arbitrary. The number of the plurality of semiconductor layers is arbitrary. The number of the plurality of holes is arbitrary.

The thickness of each of the plurality of semiconductor layers, for example, is equal to or greater than 10 nm and is equal to or smaller than 1000 nm. The thickness of each of the plurality of semiconductor layers, for example, is approximately 100 nm. The size (for example, a length along the X-axis direction) of the plurality of holes is equal to or greater than 10 nm and is equal to or smaller than 100 nm. The size of the plurality of holes, for example, is approximately 20 nm. The size of the plurality of holes is equal to or greater than 10 nm and is equal to or smaller than 100 nm, and thus, for example, the effective heat resistance of the device can be increased without excessively increasing the effective electric resistance of the device.

In this example, an interlayer insulating layer is provided between each of the plurality of semiconductor layers. As illustrated in FIG. 2B, each of the first to fourth stacked bodies S01 to S04 includes a plurality of first to fourth interlayer insulating layers IL1 to IL4. The first interlayer insulating layer IL1 is provided between each of the plurality of the first semiconductor layers 11. The second interlayer insulating layer IL2 is provided between each of the plurality of second semiconductor layers 12. The third interlayer insulating layer IL3 is provided between each of the plurality of third semiconductor layers 13. The fourth interlayer insulating layer IL4 is provided between each of the plurality of fourth semiconductor layers 14. Each of these interlayer insulating layers, for example, contains at least one component selected from a group consisting of silicon oxide, silicon nitride, silicon oxynitride, and aluminum oxide.

These interlayer insulating layers may be omitted. In this case, the plurality of semiconductor layers may be supported in a spaced apart relationship by their connection to the connection portion or the like.

As illustrated in FIGS. 2A, 2C, and 2D, for example, the first connection portion 31 includes a first connection region 31a, a second connection region 31b, and a third connection region 31c. The first connection region 31a electrically connects the plurality of first semiconductor layers 11 to each other. The second connection region 31b electrically connects the plurality of second semiconductor layers 12 to each other. The third connection region 31c electrically connects the first connection region 31a and the second connection region 31b to each other.

For example, the plurality of first semiconductor layers 11 may be supported by the first connection region 31a. For example, the plurality of second semiconductor layers 12 may be supported by the second connection region 31b. In such a case, the interlayer insulating layer described above may be omitted.

As illustrated in FIG. 2A, each (at least one) of the plurality of first semiconductor layers 11 includes a first end portion 11p and a second end portion 11q. A second direction extending between the first end portion 11p and the second end portion 11q intersects the first direction (the Z-axis direction). In this example, the second direction is the Y-axis direction.

Each (at least one) of the plurality of second semiconductor layers 12 includes a third end portion 12r and a fourth end portion 12s. A direction extending between the third end portion 12r and the fourth end portion 12s is along the second direction (for example, the Y-axis direction).

A direction extending between the first end portion 11p and the third end portion 12r through the first connection portion 31 is along a third direction. The third direction intersects the first direction and the second direction. In this example, the third direction is the X-axis direction. A direction between the facing ends of the second end portion 11q and the fourth end portion 12s is along the third direction (the X-axis direction). The first connection portion 31 electrically connects the first end portion 11p and the third end portion 12r to each other. The third end portion 12r and one end of the third stacked body S03 may be electrically connected to each other by another connection portion.

The connection portion (for example, the first to third connection portions 31 to 33), the first terminal 38a and the second terminal 38b are conductive. Each of the connection portion, the first terminal 38a, and the second terminal 38b, for example, contains metal. The metal contains at least one component that is selected from a group consisting of tungsten, molybdenum, titanium, copper, and aluminum. The connection portion, the first terminal 38a, and the second terminal 38b, for example, may contain nitride such as TiN. The connection portion, the first terminal 38a, and the second terminal 38b may contain metal silicide.

An example of a method of manufacturing the thermoelectric conversion device 110 will be described below.

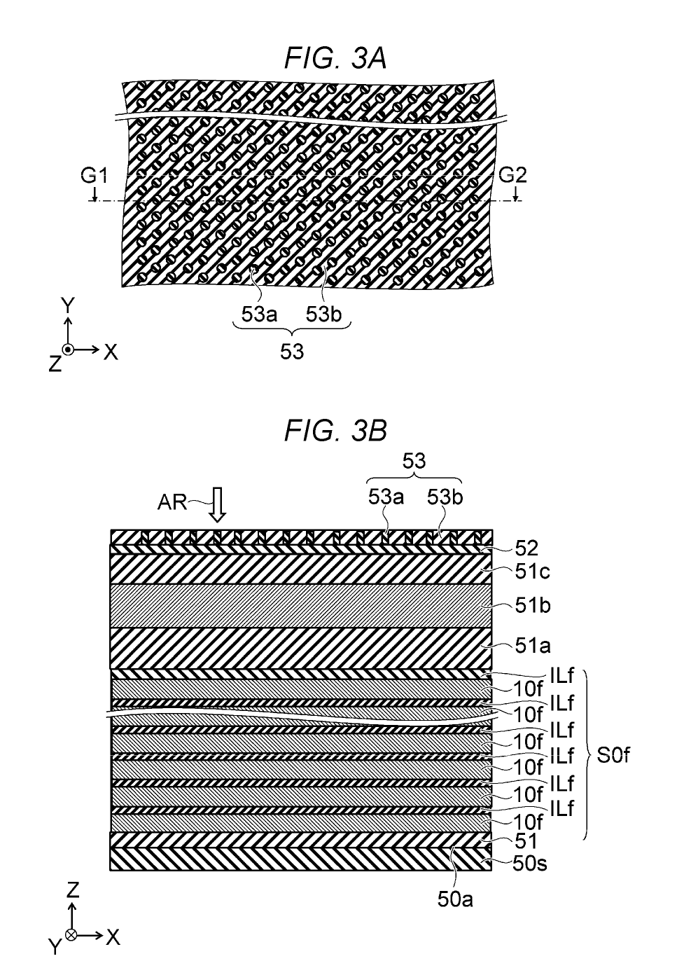

FIG. 3A to FIG. 7B are schematic diagrams illustrating a method of manufacturing the thermoelectric conversion device according to the first embodiment.

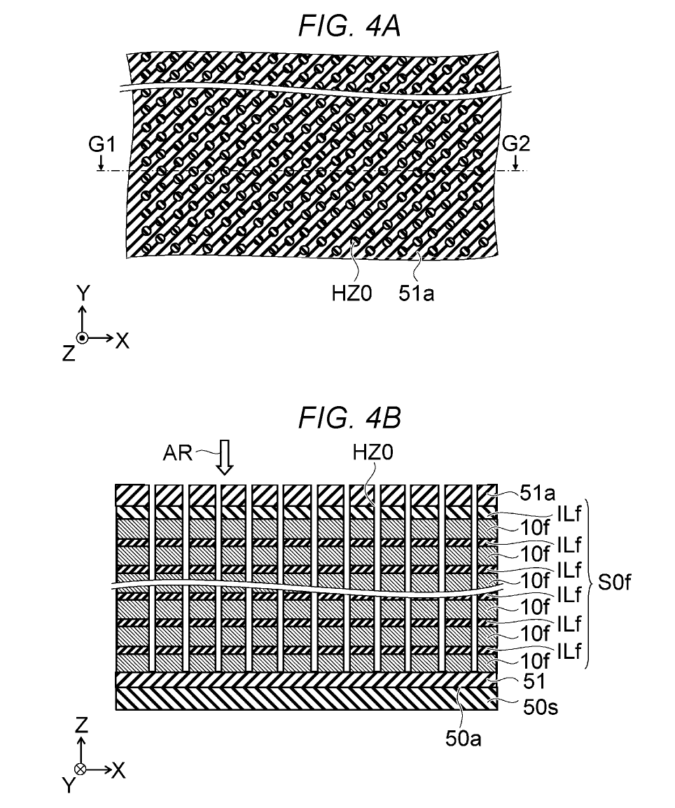

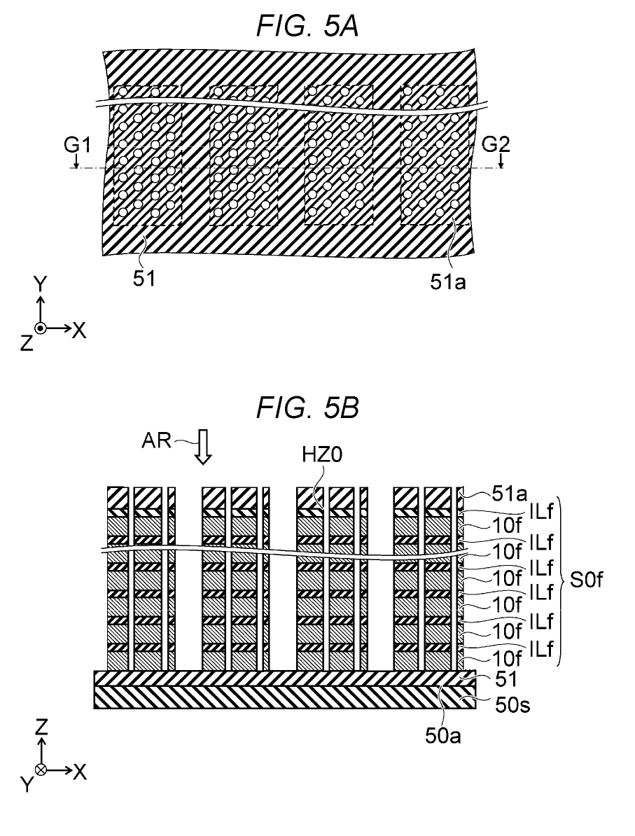

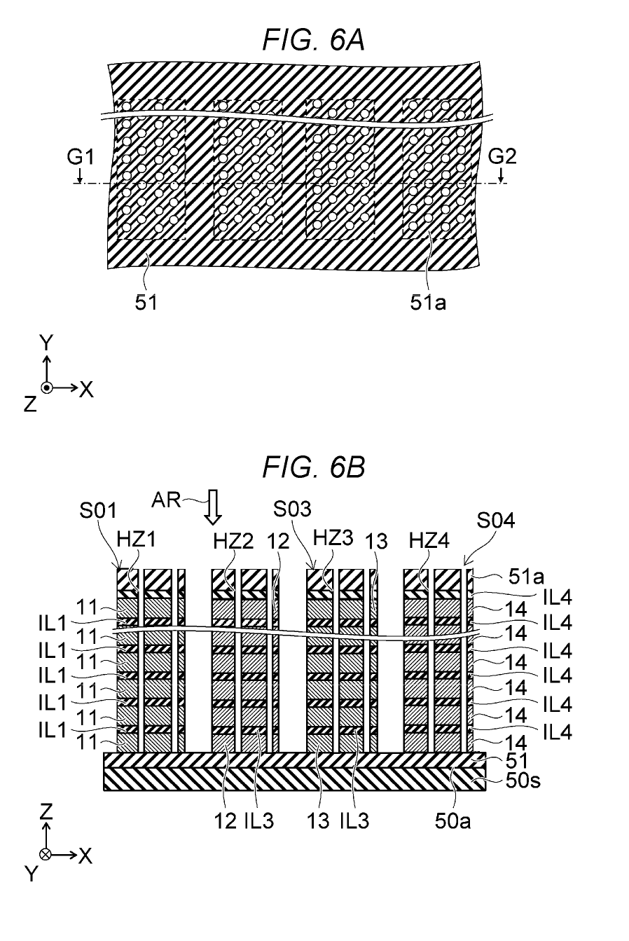

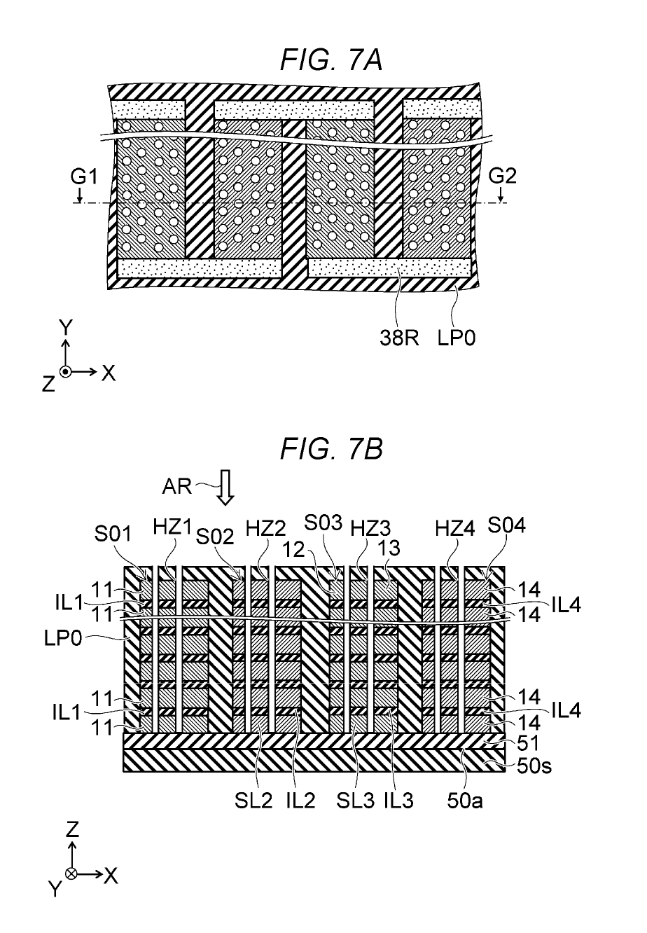

FIG. 3A, FIG. 4A, FIG. 5A, FIG. 6A and FIG. 7A are plan views when viewed in the direction of an arrow AR that is illustrated in FIG. 3B, FIG. 4B, FIG. 5B, FIG. 6B, and FIG. 7B, respectively. FIG. 3B, FIG. 4B, FIG. 5B, FIG. 6B, and FIG. 7B are sectional views taken along line G1-G2 that is illustrated in FIG. 3A, FIG. 4A, FIG. 5A, FIG. 6A, and FIG. 7A, respectively.

As illustrated in FIG. 3B, the insulating layer 51 (for example, a silicon oxide film) is formed on an upper surface (a surface 50a) of the base body 50s (for example, a silicon substrate). A stacked film S0f is formed on the insulating layer 51. In forming a stacked film S0f, a semiconductor film 10f and an insulating film ILf are alternately formed in a repeated manner. The semiconductor film 10f, for example, is silicon. The thickness of one semiconductor film 10f is approximately 100 nm. The semiconductor film 10f, for example, is formed using Chemical Vapor Deposition (CVD). The insulating film ILf, for example, is a silicon oxide film. The thickness of one insulating film ILf is approximately 10 nm. The insulating film ILf, for example, is formed using CVD. The number of the plurality of semiconductor films 10f is, for example, 25. The number of the plurality of insulating films ILf, for example, is 25. These numbers are arbitrary but the number of each is the same.

A silicon oxide film 51a is formed on the stacked film S0f using CVD. The thickness of the silicon oxide film 51a is approximately 500 nm. A border between the silicon oxide film 51a and the uppermost insulating film ILf that is included in the stacked film S0f may not be clear, and they may be formed as one layer. An organic-containing film 51b is formed on the silicon oxide film 51a, for example, using spin coating. The thickness of the organic-containing film 51b is approximately 300 nm. The organic-containing film 51b contains carbon. An insulating film 51c is formed on the organic-containing film 51b. An insulating film 51c, for example, is a Spin-On-Glass (SOG) film. The thickness of the insulating film 51c is approximately 50 nm.

Next, a fine pattern is formed using block copolymer. A neutral film 52 that has affinity to both blocks of a block copolymer is formed on the insulating film 51c. A block copolymer film 53 is formed on the neutral film 52 using spin coating. In this example, a cylinder type is used for a block copolymer film. After the block copolymer 53 is applied by spin coating, for example, annealing is performed at 250° C. for one minute. Accordingly, phase separation occurs, and thus, a fine pattern is formed by self-organization of the block copolymer film 53.

The block copolymer film 53 includes a plurality of first film portions 53a and a second film portion 53b. The plurality of first film portions 53a are surrounded by the second film portion 53b in the X-Y plane. The pitch (space between centers) of the plurality of first film portions 53a is approximately 40 nm. The size (a distance along the X-Y plane) of one of the plurality of first film portions 53a is approximately 20 nm. The front surface energy of the neutral film 52, for example, is between the front surface energies of a plurality of types of radicals that are included in the block copolymer film. Accordingly, the plurality of first film portions 53a extend in the Z-axis direction. A cylinder-shaped structure is completed. The plurality of first film portions 53a, for example, are arranged in a substantially hexagonal pattern.

Thereafter, the plurality of first film portions 53a are removed. The removal, for example, is performed by at least any one of wet etching and dry etching. Accordingly, a plurality of holes are formed in the hexagonal pattern. A hole size (width) of a hole in the hexagonal pattern, for example, is approximately 20 nm. Using the holes in the hexagonal pattern of the plurality of first film portions 53a as a patterned mask, the neutral film 52 is processed, and the insulating film 51c, the organic-contained film 51b, and the silicon oxide film 51a are processed. For at least one part of the process, for example, Reactive Ion Etching (RIE) is used. Additionally, the stacked film S0f is processed.

Accordingly, as illustrated in FIGS. 4A and 4B, a plurality of holes HZ0 are formed on the stacked film S0f. The plurality of holes HZ0 extend in the first direction (the Z-axis direction) through the stacked film S0f. An opening size (width) of one of the plurality of holes HZ0 is approximately 20 nm.

Thereafter, a resist film is formed, and lithography is performed. In the lithography step, portions that correspond to the semiconductor layers of the stacked bodies remain left behind. Using the resist film as a mask, a portion of the stacked film S0f is removed.

Accordingly, as illustrated in FIGS. 5A and 5B, a portion is formed that results in first to fourth stacked bodies S01 to S04.

Thereafter, impurities are introduced into the portions of the semiconductor films 10f that result in the first to fourth stacked bodies S01 to S04. For example, the first conductivity type (for example, n type) impurities are introduced into the portion thereof that results in the first stacked body S01 and the third stacked body S03. For example, the second conductivity type (for example, p type) impurities are introduced into the portion thereof that results in the second stacked body S02 and the fourth stacked body S04. The method for introduction of the impurities, for example, includes ion implantation.

Accordingly, as illustrated in FIGS. 6A and 6B, first to fourth semiconductor layers 11 to 14 are formed. The insulating film ILf between each of the plurality of first semiconductor layers 11 results in the first interlayer insulating layer ILL The insulating film ILf between each of the plurality of second semiconductor layers 12 results in the second interlayer insulating layer IL2. The insulating film ILf between each of the plurality of third semiconductor layers 13 results in the third interlayer insulating layer IL3. The insulating film ILf between each of the plurality of fourth semiconductor layers 14 results in the fourth interlayer insulating layer IL4. Accordingly, the first to fourth stacked bodies S01 to S04 are formed.

Thereafter, an insulating material is buried (deposited) between each of the first to fourth stacked bodies S01 to S04, and flattening of the insulating material is performed using Chemical Mechanical Polishing (CMP) or the like. Additionally, one portion of the insulating material is removed. The portion that is removed corresponds to a region that results in the connection portion or the like. For the removal, for example, lithography and RIE are used.

Accordingly, as illustrated in FIG. 7A, recesses 38R are formed.

A conductive material (for example, tungsten or the like) is buried (deposited) in the recess 38R. Accordingly, the connection portions (the first to third connection portions 31 to 33), and the first terminal 38a and the second terminal 38b are thus formed.

When processing is performed as described above, the thermoelectric conversion device 110 is formed. In the manufacturing method described above, instead of a self-organization film that is formed using the block copolymer 53, for example, patterning may be performed that uses EUV exposure or nanoimprint. When using the self-organization film, it is easy to reduce cost.

In the manufacturing method, the plurality of holes HZ0 can be collectively formed on the stacked film S0f. Accordingly, the plurality of holes extend in the plurality of semiconductor layers (in the stacked body) in the first direction.

For example, there is a second reference example in which a plurality of structured bodies are arranged on a substrate. In the second reference example, each of the plurality of structured bodies includes a p type semiconductor layer and an n type semiconductor layer. The plurality of structured bodies are independently manufactured and then are arranged on the substrate. In the second reference example, an interconnection that electrically connects the plurality of structured bodies to each other is independently formed. In this case, it is easy for a connection defect to occur. For example, it is easy for peeling away of the connection portion to occur due to mechanical shock, stress, or the like. In some cases, reliability is insufficient.

In contrast, in the manufacturing method described above, the connection portions can be collectively formed. For this reason, reliable electric connections are obtained. For example, high reliability is obtained.

In the manufacturing method described above, the plurality of stacked bodies and the plurality of holes are collectively formed. For this reason, it is easy to reduce cost.

In the manufacturing method described above, instead of the method that uses the self-organization film, at least any one of lithography that uses light, EUV lithography, nanoimprint, and EB drawing may be used.

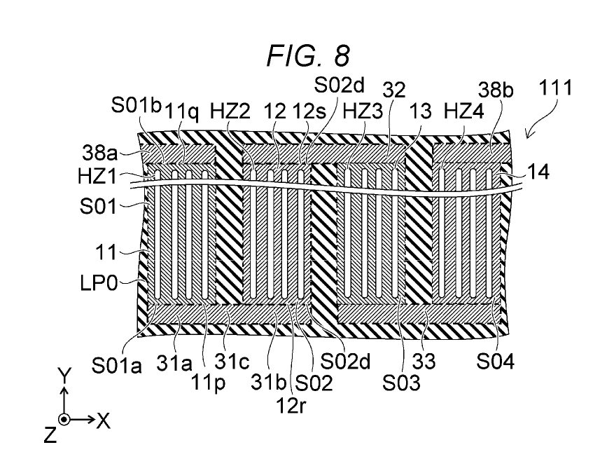

FIG. 8 is a schematic plan diagram illustrating another thermoelectric conversion device according to the first embodiment.

As illustrated in FIG. 8, another thermoelectric conversion device 111 according to the present embodiment also includes the plurality of stacked bodies (for example, the first to fourth stacked bodies S01 to S04) and the connection portions (the first to third connection portions 31 to 33). The first to fourth stacked bodies S01 to S04 have the first to fourth holes HZ1 to HZ4, respectively.

In the thermoelectric conversion device 111, each of the first to fourth holes HZ1 to HZ4 extend in the Y-axis direction. For example, the length in the second direction (the Y-axis direction), of one of the plurality of first holes HZ1 is longer than the length along the third direction (the X-axis direction), of the one of the plurality of first holes HZ1. The distance in the third direction (the X-axis direction) between adjacent two of the plurality of first holes HZ1, for example, is equal to or greater than 10 nm and is equal to or smaller than 300 nm.

Also in thermoelectric conversion device 111, the power that is obtained per unit area can also be increased. With a plurality of fine patterns, a great temperature difference is easy to maintain. An output with high efficiency of thermoelectric conversion is obtained.

### Second Embodiment

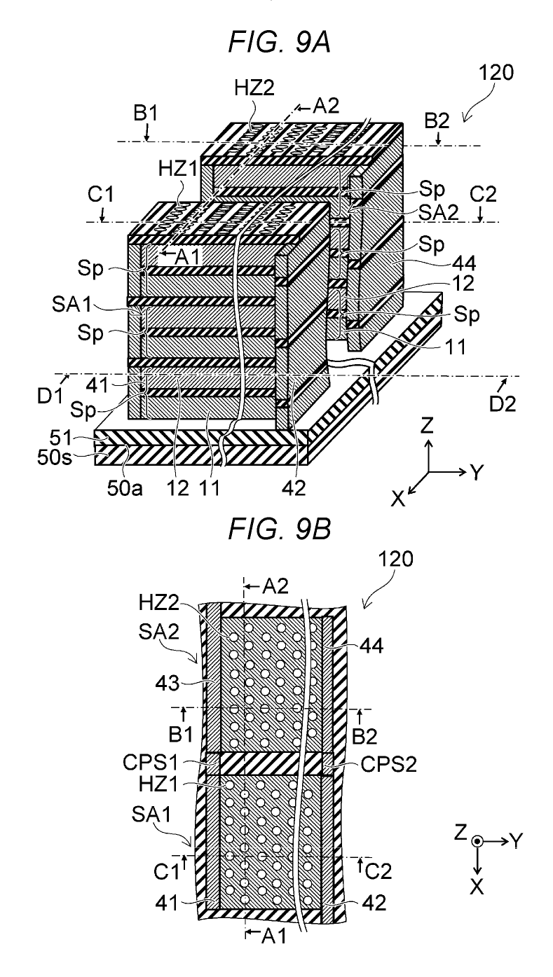

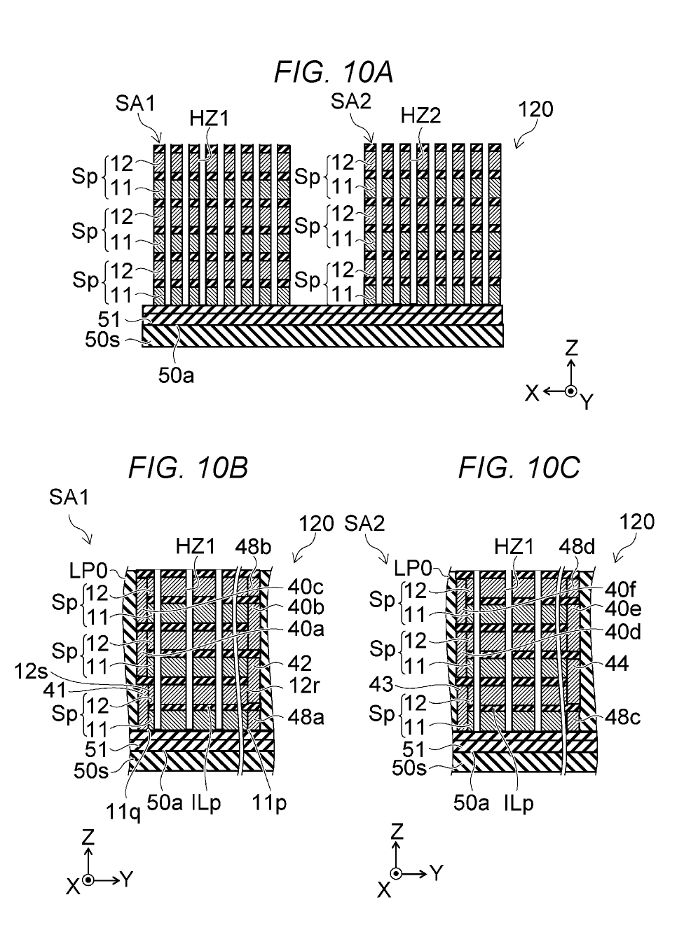

FIGS. 9A and 9B, and FIGS. 10A to 10C are schematic diagrams illustrating a thermoelectric conversion device according to a second embodiment.

FIG. 9A is a perspective view. In FIG. 9A, some constituent elements are omitted. FIG. 9B is a sectional view taken along line D1-D2 in FIG. 9A. FIG. 10A is a sectional view taken along line A1-A2 in FIGS. 9A and 9B. FIG. 10B is a sectional view taken along line B1-B2 in FIGS. 9A and 9B. FIG. 10C is a sectional view taken along line C1-C2 in FIGS. 9A and 9B.

As illustrated in FIG. 9A, the thermoelectric conversion device 120 includes a first stacked body SA1 and a first connection portion 41.

The first stacked body SA1 includes a plurality of stacked portions Sp. The plurality of stacked portion Sp are spaced apart from each other in the first direction (for example, the Z-axis direction).

As illustrated in FIGS. 10A and 10B, each of the plurality of stacked portions Sp includes the first semiconductor layer and the second semiconductor layer 12. The first semiconductor layer 11 is of the first conductivity type (for example, the n type). The second semiconductor layer 12 is of the second conductivity type (for example, the p type). Each second semiconductor layer 12 is spaced from the adjacent first semiconductor layer (s) 11 in the first direction (the Z-axis direction).

In this example, an interlayer insulating layer ILp is provided between the first semiconductor layer 11 and the second semiconductor layer 12. Additionally, the interlayer insulating layer ILp is provided also between each of the plurality of stacked portion Sp. These interlayer insulating layers ILp may be omitted as described further herein.

The first stacked body SA1 has a plurality of first holes HZ1. The plurality of first holes HZ1 extend in the plurality of stacked portion Sp in the first direction (the Z-axis direction). The plurality of first holes HZ1 extend through the first stacked body SA1 in the first direction (the Z-axis direction).

As illustrated in FIG. 10B, the first connection portion 41 electrically connects the first semiconductor layer 11 of one of the plurality of stacked portions Sp and the second semiconductor layer 12 of the same one of the plurality of stacked portions Sp to each other.

In this example, a second connection portion 42 is further provided. The second connection portion 42 electrically connects the second semiconductor layer 12 of the one of the plurality of stacked portions Sp and the first semiconductor layer 11 of another one of the plurality of stacked portions Sp, to each other.

For example, in the first stacked body SA1, the first semiconductor layer 11 and the second semiconductor layer 12 that are included in each of the plurality of stacked portions Sp are connected to each other. The plurality of stacked portions Sp are connected in series to each other.

For example, one thermoelectric stacked portion Sp results in one thermoelectric conversion portion. A plurality of thermoelectric conversion portions are stacked on top of one another, and are connected in series to each other. Accordingly, the power that is obtained per unit area can be increased. Then, in the first stacked body SA1, the plurality of first holes HZ1 are provided. Accordingly, a large temperature difference is easy to maintain. Also in the thermoelectric conversion device 120, the thermoelectric conversion device that can improve power output per unit area can be provided.

As illustrated in FIG. 10B, for example, the first semiconductor layer 11 included in the one of the plurality of stacked portions Sp includes the first end portion 11p and the second end portion 11q. The second direction extending between the first end portion 11p and the second end portion 11q intersects the first direction (the Z-axis direction). In this example, the second direction is the Y-axis direction.

The second semiconductor layer 12 that is included in the one of the plurality of stacked portions Sp includes the third end portion 12r and the fourth end portion 12s. The direction extending between the third end portion 12r and the fourth end portion 12s is the second direction (the Y-axis direction). The direction extending between the first end portion 11p and the third end portion 12r is the first direction (the Z-axis direction). The direction extending between the second end portion 11q and the fourth end portion 12s is the first direction (the Z-axis direction). The first connection portion 41 electrically connects the second end portion 11q and the fourth end portion 12s to each other.

For example, connection portions, such as the first connection portion 41, the second connection portion 42, a connection portion 40a, a connection portion 40b, and a connection portion 40c, connect the first semiconductor layer 11 and the second semiconductor layer 12 to each other in series.

In this example, a first terminal 48a and a second terminal 48b are provided. The first terminal 48a is electrically connected to a semiconductor layer (the first semiconductor layer 11 in this example) that is at one end of a series connection of semiconductor layers 11, 12 of a first stacked portion Sp, and is included in the first stacked body SA1. The second terminal 48b is electrically connected to a semiconductor layer (the second semiconductor layer 12 in the example) that is at the other end of a series connection of semiconductor layers 11, 12 at a different stacked portion Sp of the first stacked body SA1. A current flows between the first terminal 48a and the second terminal 48b when they are connected across a load.

As illustrated in FIGS. 9A, 10A, and 10C, in this example, a second stacked body SA2 is further provided in the thermoelectric conversion device 120. The first stacked body SA1 and the second stacked body SA2 are provided on the surface 50a of the base body 50s. In this example, the insulating layer 51 is provided between the base body 50s and the stacked bodies SA1, SA2. A configuration of the second stacked body SA2 is the same as a configuration of the first stacked body SA1, and thus a description thereof is omitted.

As illustrated in FIG. 10C, on the second stacked body SA2, a third connection portion 43 and a fourth connection portion 44 are provided. In the second stacked body SA2, the third connection portion 43 electrically connects the first semiconductor layer 11 of one of the plurality of stacked portions Sp, and the second semiconductor layer 12 of the same one of the plurality of stacked portions Sp, to each other. In the second stacked body SA2, the fourth connection portion 44 electrically connects the second semiconductor layer 12 of the one of the plurality of stacked portions Sp and the first semiconductor layer 11 of another one of the plurality of stacked portions Sp, to each other. Also in the second stacked body SA2, connection portions, such as the third connection portion 43, the fourth connection portion 44, a connection portion 40d, a connection portion 40e, and the connection portion 40f, electrically connect the first semiconductor layer 11 and the second semiconductor layer 12 to each other in series.

In the second stacked body SA2, the third terminal 48c and the fourth terminal 48d are provided. The third terminal 48c is electrically connected to a semiconductor layer (the first semiconductor layer 11 in this example) that is one end of the series connection of stacked portions Sp included in the second stacked body SA2. The fourth terminal 48d is electrically connected to a semiconductor layer (the second semiconductor layer 12 in the example) that is at the other end of the series connection of stacked portions Sp in the second stacked body SA2. A current flows between the third terminal 48c and the fourth terminal 48d when they are connected across a load.

In this example, the first stacked body SA1 and the second stacked body SA2 are connected together in parallel. As illustrated in FIG. 9B, a first inter-stacked-body connection portion CPS1 and a second inter-stacked-body connection portion CPS2 are provided. These inter-stacked-body connection portions, for example, electrically connect one connection portion included in the first stacked body SA1, and one connection portion that is included in the second stacked body SA2, to each other. The connection portions included in the first stacked body SA1 is one of the first connection portion 41, the second connection portion 42, the connection portion 40a, the connection portion 40b, the connection portion 40c, the first terminal 48a, the second terminal 48b, and the like. The connection portions included in the second stacked body SA2 is one of the third connection portion 43, the fourth connection portion 44, the connection portion 40d, the connection portion 40e, the connection portion 40f, the third terminal 48c, the fourth terminal 48d, and the like. In this example, the first inter-stacked-body connection portion CPS1 electrically connects together the first terminal 48a and the third terminal 48c. The second inter-stacked-body connection portion CPS2 electrically connects together the second terminal 48b and the fourth terminal 48d.

In the first stacked body SA1 according to the present embodiment, the plurality of stacked portions Sp may be arbitrarily configured. For example, one first semiconductor layer 11 and the second semiconductor layer 12 over the first semiconductor layer 11 are described as a single stacked portion Sp as illustrated in FIG. 10B. According to the embodiment, one second semiconductor layer 12 and the first semiconductor layer 11 over the second semiconductor layer 12 may be regarded as one stacked portion Sp. In this case, for example, the second connection portion 42 illustrated in FIG. 10B may be regarded as a “first connection portion”.

According to the present embodiment, the configuration and the materials that are described according to the first embodiment can apply to the first semiconductor layer 11, the second semiconductor layer 12, the interlayer insulating layer, the base body 50s, the insulating layer 51, and the insulating portion LP0.

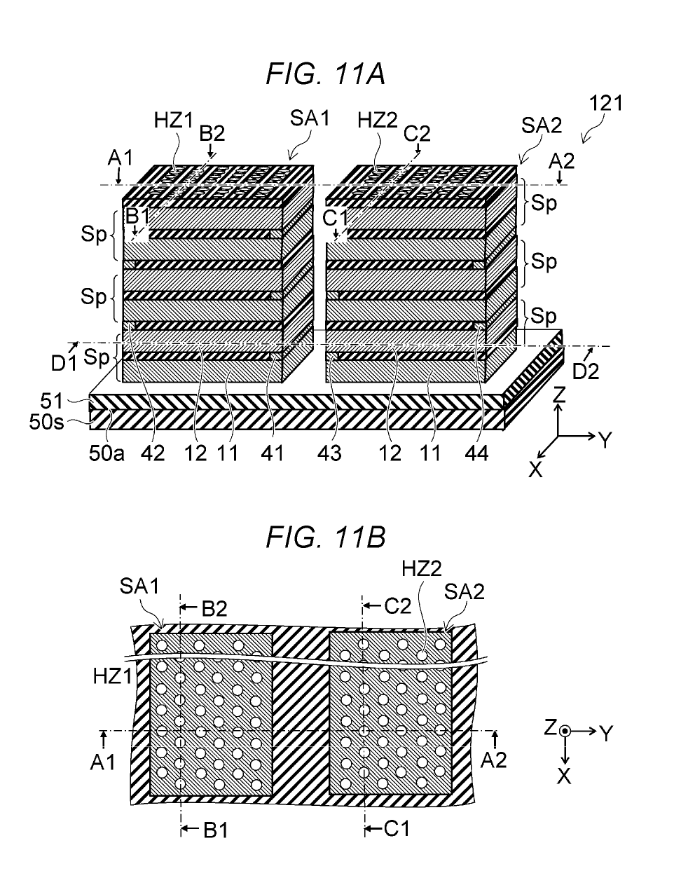

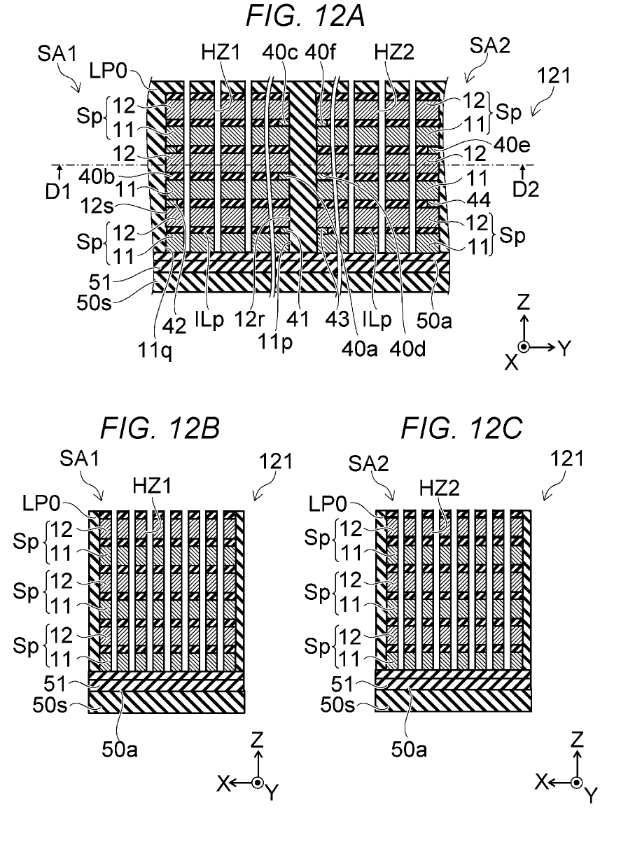

FIGS. 11A, 11B and FIGS. 12A and 12C are schematic views illustrating another thermoelectric conversion device according to the second embodiment.

FIG. 11A is a perspective view. In FIG. 11A, some constituent elements are omitted. FIG. 11B is a sectional view taken along line D1-D2 in FIGS. 11A and 12A. FIG. 12A is a sectional view taken along line A1-A2 in FIGS. 11A and 11B. FIG. 12B is a sectional view taken along line B1-B2 in FIGS. 11A and 11B. FIG. 12C is a sectional view taken along line C1-C2 in FIGS. 11A and 11B.

As illustrated in FIG. 11A, in a thermoelectric conversion device 121 according to the present embodiment, at least one part of the connection portion is provided, in the Z-axis direction, between two semiconductor layers. Except for this difference, for example, thermoelectric conversion device 121 is the same as the thermoelectric conversion device 120. An example of a connection portion in the thermoelectric conversion device 121 will be described below.

As illustrated in FIG. 11A and FIG. 12A, the first connection portion 41 electrically connects together the first semiconductor layer 11 included in one of the plurality of stacked portions Sp and the second semiconductor layer 12 included in one of the plurality of stacked portions Sp. At least one part of the first connection portion 41 electrically connects together the first semiconductor layer 11 included in one of the plurality of stacked portions Sp and the second semiconductor layer 12 included in the same one of the plurality of stacked portions Sp.

The second connection portion 42 electrically connects together the second semiconductor layer 12 included in one of the plurality of stacked portions Sp and the first semiconductor layer 11 included in another one of the plurality of stacked portions Sp. At least one part of the second connection portion 42 is provided between the second semiconductor layer 12 included in one of the plurality of stacked portions Sp and the first semiconductor layer 11 included in another one of the plurality of stacked portions Sp.

Thus, in this example, substantially the entirety of one connection portion 41, or 42 is provided between each of the plurality of semiconductor layers 11, 12 at adjacent ends thereof. In the thermoelectric conversion device 121, for example, the connection portion does not protrude around or over the end of the semiconductor layer. Accordingly, an area that is occupied by one stacked body can be decreased. For example, in a case where the plurality of stacked bodies are provided on a substrate, the distance between each of the plurality of stacked bodies can be reduced. Thus, the power that is obtained per unit area can be increased.

Also in the thermoelectric conversion device 121, the thermoelectric conversion device having improved output per unit area can be provided.

An example of a method of manufacturing the thermoelectric conversion device 121 will be described below.

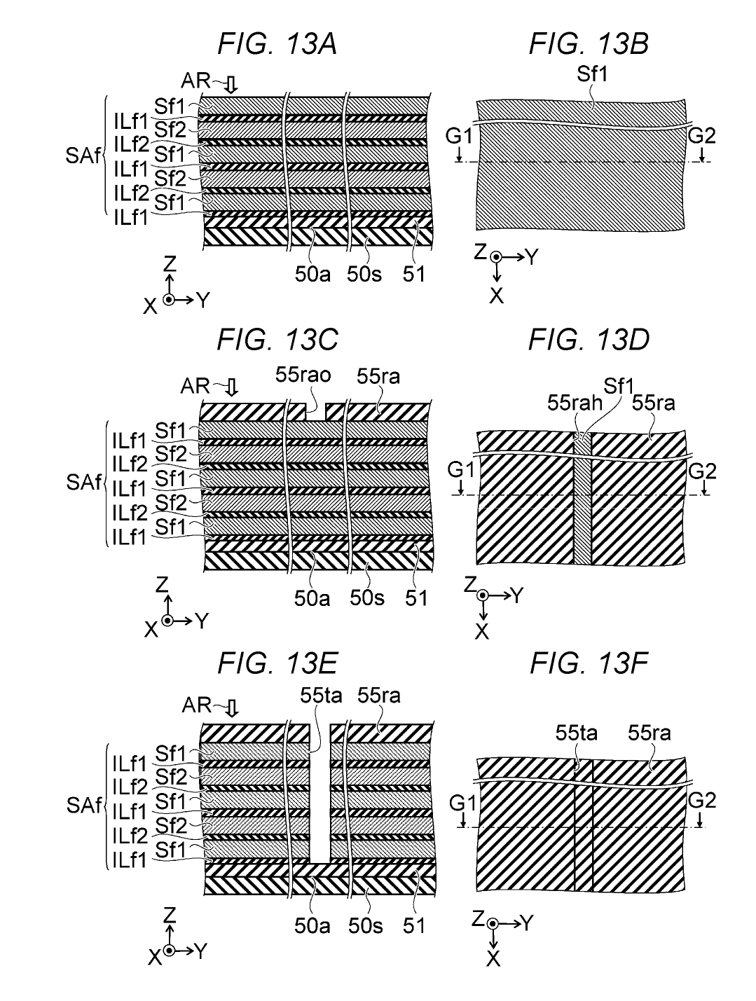

FIG. 13A to FIG. 17F are schematic views illustrating a method of manufacturing the thermoelectric conversion device according to the second embodiment.

FIGS. 13A, 13C, and 13E, FIGS. 14A, 14C, and 14E, FIGS. 15A, 15C, and 15E, FIGS. 16A, 16C, and 16E, and FIGS. 17A, 17C, and 17E are sectional views taken along line G1-G2 in FIGS. 13B, 13D, and 13F, FIGS. 14B, 14D, and 14F, FIGS. 15B, 15D, and 15F, FIGS. 16B, 16D, and 16F, and FIGS. 17B, 17D, and 17F, respectively.

As illustrated in FIGS. 13A and 13B, the insulating layer 51 is shown provided on the surface 50a of the base body 50s (for example, the silicon substrate). A stacked film SAf is formed on the insulating layer 51. In this example, the stacked film SAf includes a first film ILf1 provided on the insulating layer 51, a first semiconductor film Sf1 provided on the first film ILf1, a second film ILf2 provided on the first semiconductor film Sf1, and a second semiconductor film Sf2 provided on the second film ILf2. These four films result in one set of films. A plurality of these sets are stacked one on top of one another.

The material of the second film ILf2 is different from the material of the first film ILf1. For example, the etching rate for at least one etchant of the films ILf1 and ILf2 differs for these two films. For example, the first film ILf1 contains silicon oxide. The second film ILf2 contains silicon nitride.

The first semiconductor film Sf1, for example, contains a semiconductor (for example, silicon) that is the first conductivity type. The second semiconductor film Sf2, for example, contains a semiconductor (for example, silicon) that is the second conductivity type.

As illustrated in FIGS. 13C and 13D, a first mask 55ra (a resist film) is formed over the film stack. The first mask 55ra has a first opening 55rao. For example, photolithography is used for the formation of the first opening 55rao.

As illustrated in FIGS. 13E and 13F, one portion of the stacked film SAf is removed using the first mask 55ra as a mask. For the removal, for example, RIE is performed. Accordingly, a first groove 55ta is formed.

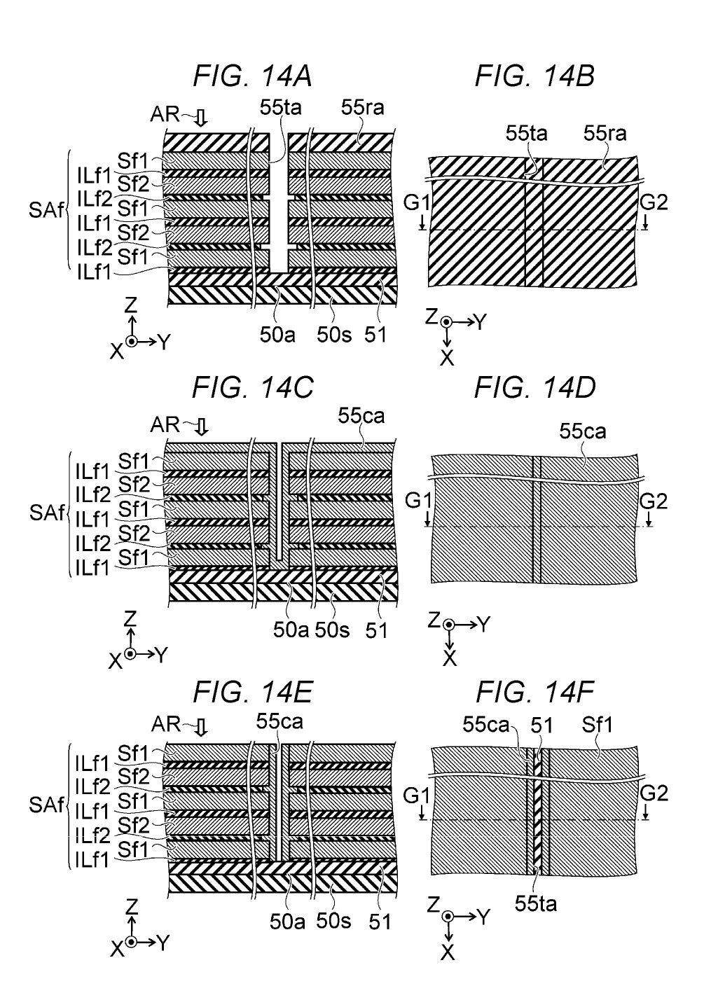

As illustrated in FIGS. 14A and 14B, selective etching is then performed, and the second film ILf2 is etched outwardly to retreat between adjacent semiconductor films Sf1, Sf2. The selective etching, for example, includes a process that uses phosphoric acid.

As illustrated in FIGS. 14C and 14D, the first mask 55ra is removed, and then a first conductive film 55ca is formed. The first conductive film 55ca, for example, is a metal film (for example, a tungsten film). This formation, for example, is performed using CVD.

As illustrated in FIGS. 14E and 14F, etching-back of the first conductive film 55ca is performed. For example, the portion of the first conductive film 55ca that is provided on the stacked film SAf is removed. The first conductive film 55ca that is provided on the side surface of the first groove 55ta remains behind.

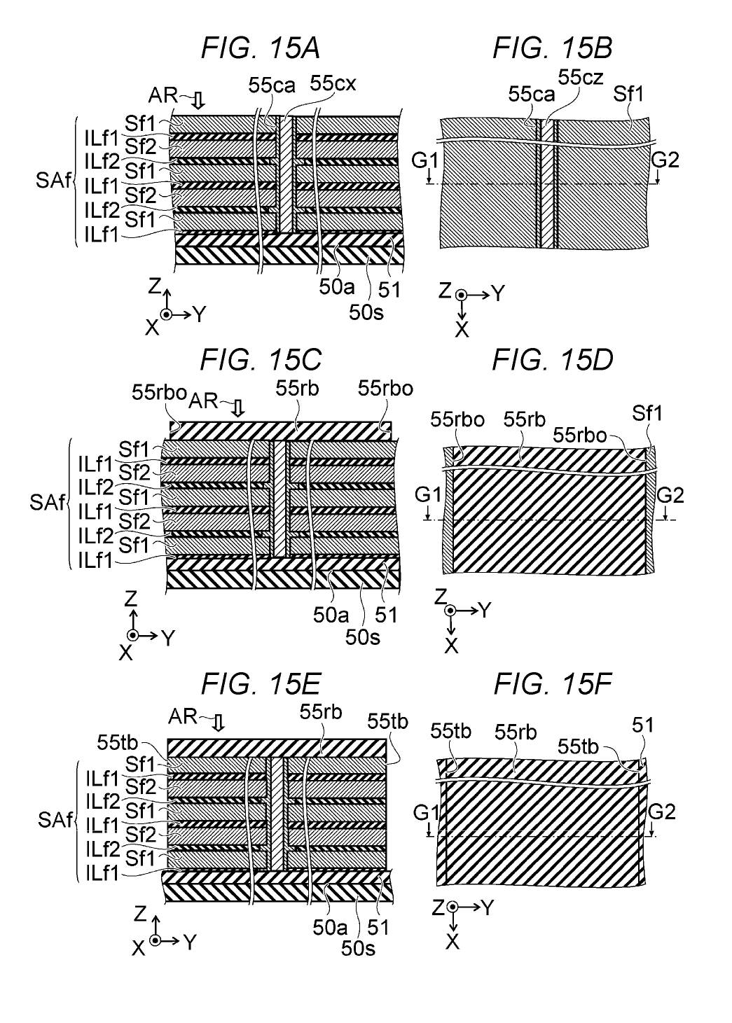

As illustrated in FIGS. 15A and 15B, an intermediate member 55cx is buried into the first groove 55ta and then flattening is performed. The intermediate member 55cx, for example, is made of insulating material. The flattening, for example, includes CMP.

As illustrated in FIGS. 15C and 15D, a second mask 55rb is formed. The second mask 55rb has a second opening 55rbo. The region between the first opening 55rao and the second opening 55rbo, which are already described, corresponds to a region for the stacked body.

As illustrated in FIGS. 15E and 15F, portions of the stacked film SAf defining sides of the stacked body are removed using the second mask 55rb as a mask. For the removal, for example, RIE is performed. Accordingly, second grooves 55tb are formed.

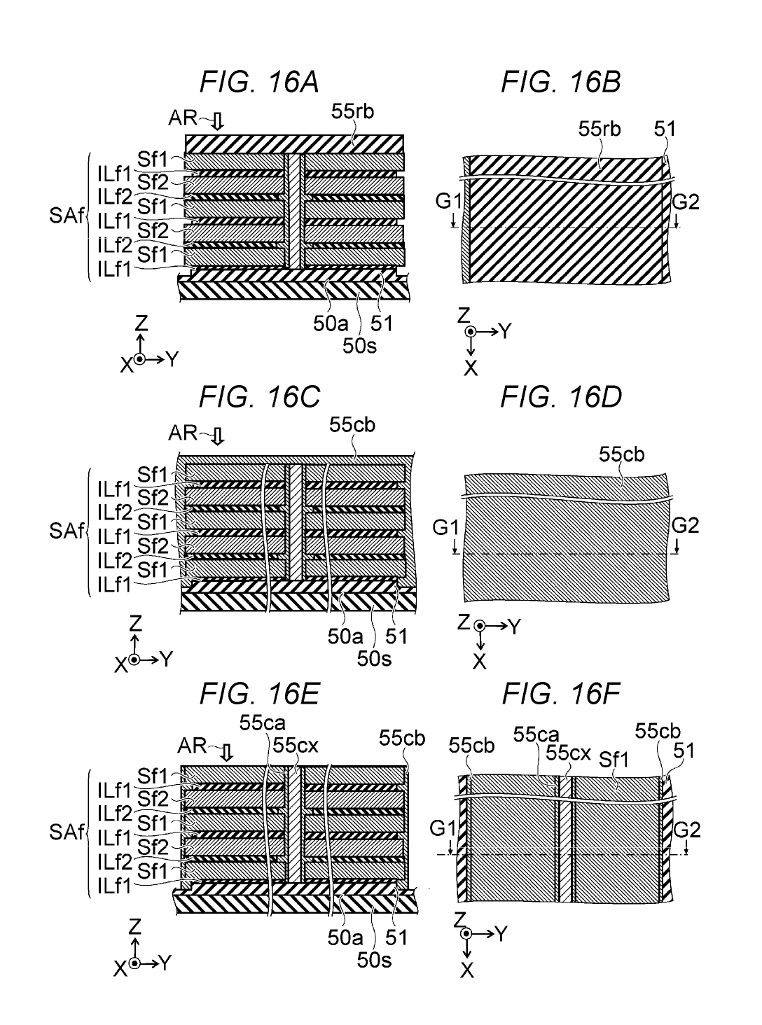

As illustrated in FIGS. 16A and 16B, selective etching is then performed, and the first film ILf1 is caused to retreat between adjacent semiconductor films SF1, Sf2. The selective etching, for example, includes a process that uses fluoric acid.

As illustrated in FIGS. 16C and 16D, the second mask 55rb is removed, and then a second conductive film 55cb is formed. The second conductive film 55cb, for example, is a metal film (for example, a tungsten film). This formation, for example, is performed using CVD.

As illustrated in FIGS. 16E and 16F, for example, etching-back is then performed using RIE. For example, the second conductive film 55cb provided on the stacked film SAf is removed. The second conductive film 55cb that is provided on a side surface of the second grooves 55tb remains behind.

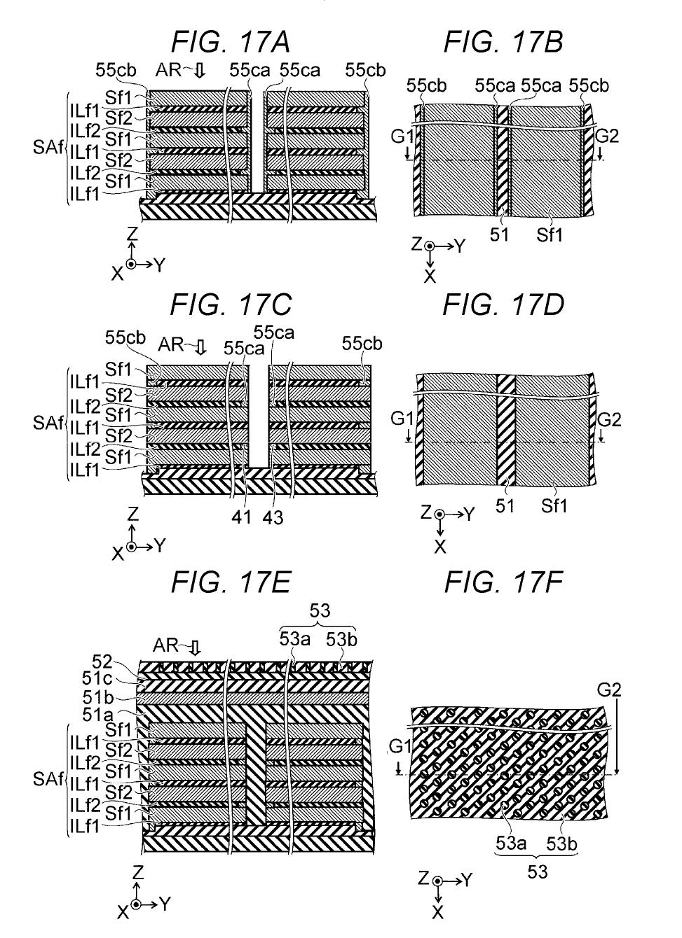

As illustrated in FIGS. 17A and 17B, the intermediate member 55cx is removed. The removal, for example, includes an etching process.

As illustrated in FIGS. 17C and 17D, one portion of the first conductive film 55ca and one portion of the second conductive film 55cb are removed. The removal, for example, includes the etching process. Accordingly, the remaining portion of the first conductive film 55ca is positioned between each two adjacent semiconductor layers in locations where the insulating film ILf1, ILf2 retreated. The remaining portion of the second conductive film 55cb is positioned between two semiconductor layers.

As illustrated in FIGS. 17E and 17F, the sides of the structure are covered with a silicon oxide film 51a, and then hole formation is performed. In this example, the process that is described with reference to FIGS. 3A and 3B is performed. The organic-containing film 51b is formed on the silicon oxide film 51a, and the insulating film 51c is formed on the organic-containing film 51b. The neutral film 52 is formed on the insulating film 51c, and the block copolymer 53 is formed on the neutral film 52. A fine pattern is obtained by the self-organization that results from phase separation. The self-organization film (the block copolymer film) includes the plurality of first film portions 53a and the second film portion 53b. Using the self-organization film, the plurality of holes (the first hole HZ1, the second hole HZ2, and the like) are formed.

When the processing is performed as described, the thermoelectric conversion device 121 is manufactured. In the hole formation step described above, at least any one of photolithography, EUV lithography, nanoimprint, or ebeam writing may apply.

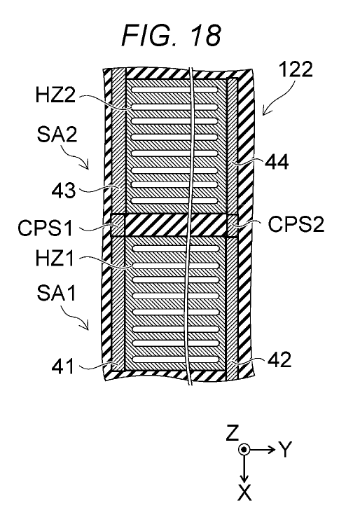

FIG. 18 is a schematic plan view illustrating another thermoelectric conversion device according to the second embodiment.

As illustrated in FIG. 18, another thermoelectric conversion device 122 according to the present embodiment also includes the plurality of stacked bodies (for example, the first and second stacked bodies S01 and S02) and the connection portions (the first to fourth connection portions 41 to 44). The first to second stacked bodies S01 to S02 have the first to second holes HZ1 to HZ2, respectively.

In the thermoelectric conversion device 122, each of the first and second holes HZ1 to HZ2 extend in the Y-axis direction. For example, the length in the X-axis direction, of one of the plurality of first holes HZ1 is less than the length thereof in the Y-axis direction of the one of the plurality of first holes HZ1. The distance in the X-axis direction between an adjacent two of the plurality of first holes HZ1, for example, is equal to or greater than 10 nm and is equal to or smaller than 300 nm.

Also in thermoelectric conversion device 122, the power that is obtained per unit area can be increased. With the plurality of holes, a great temperature difference is easy to maintain. A high thermoelectric conversion output is obtained.

### Third Embodiment

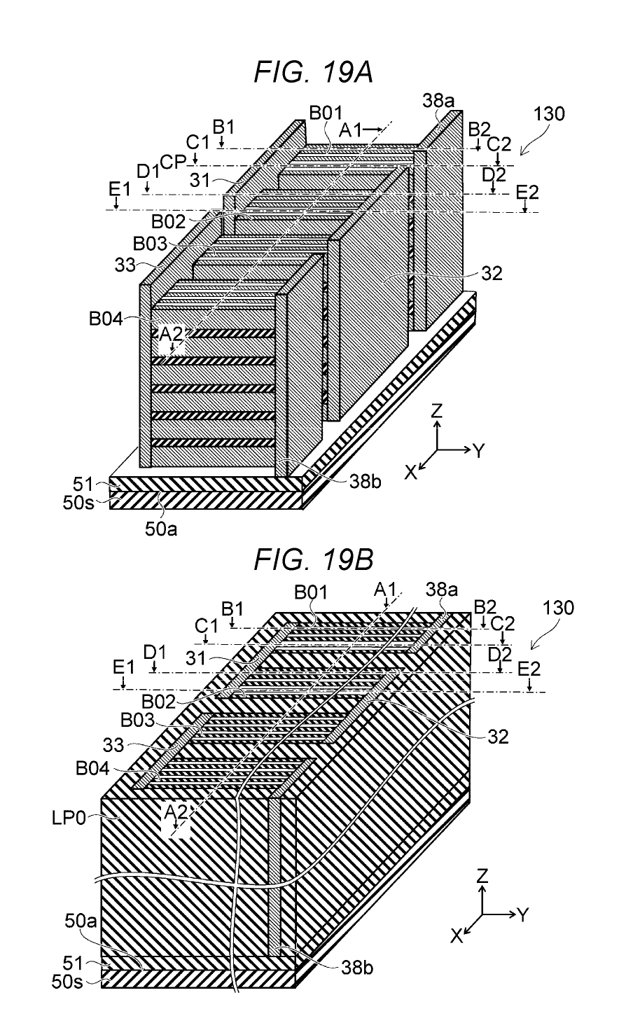

FIGS. 19A and 19B, FIGS. 20A and 20B, and FIGS. 21A to 21D are schematic views illustrating a thermoelectric conversion device according to a third embodiment.

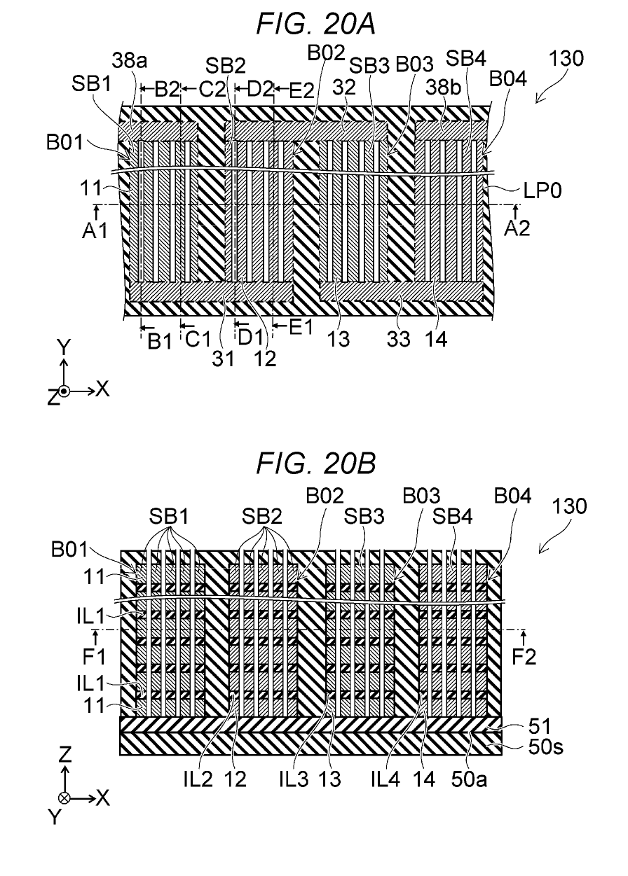

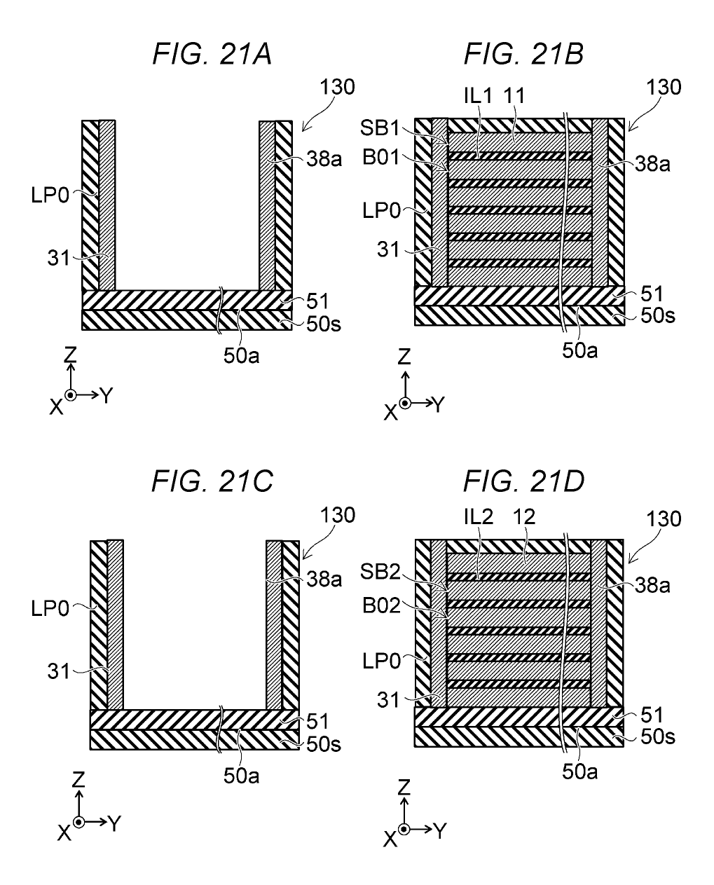

FIGS. 19A and 19B are perspective views. In FIG. 19A, some constituent elements are omitted. FIG. 20A is a sectional view along line F1-F2 in FIG. 20B. FIG. 20B is a sectional view taken along line A1-A2 in FIGS. 19A and 19, and FIG. 20A. FIG. 21A is a sectional view taken along line B1-B2 in FIGS. 19A and 19B and FIG. 20A. FIG. 21B is a sectional view taken along line C1-C2 in FIGS. 19A and 19B and FIG. 20A. FIG. 21C is a sectional view taken along line D1-D2 in FIGS. 19A and 19B and FIG. 20A. FIG. 21D is a sectional view taken along line E1-E2 in FIGS. 19A and 19B and FIG. 20A.

As illustrated in FIGS. 19A and 19B, a thermoelectric conversion device 130 according to the present embodiment includes a first structured body B01, a second structured body B02, and a connection portion CP. The connection portion CP may correspond to the first connection portion 31 that will be described below. The connection portion CP may include at least any one of the first to third connection portions 31 to 33 that will be described below.

As described in FIGS. 20A and 20B, the first structured body B01 includes a plurality of first stacked bodies SB1. The second structured body B02 includes a plurality of second stacked bodies SB2.

Each of the plurality of first stacked bodies SB1 includes the plurality of first semiconductor layers 11. The plurality of first semiconductor layers 11 are spaced from each other in the first direction (the Z-axis direction in this example).

One of the plurality of first semiconductor layers 11 (each of the plurality of first semiconductor layers 11) extends in the second direction. The second direction intersects the first direction. In this example, the second direction is the Y-axis direction. The first semiconductor layer 11 has the first conductivity type.

The plurality of first stacked bodies SB1 are spaced from each other in the third direction. The third direction intersects the first direction and the second direction. In this example, the third direction is the X-axis direction.

Each of the plurality of second stacked bodies SB2 includes the plurality of second semiconductor layers 12. The plurality of second semiconductor layers 12 are spaced apart in the first direction (the Z-axis direction). One of the plurality of second semiconductor layers 12 (each of the plurality of second semiconductor layers 12) extends in the second direction. The plurality of second semiconductor layer are the second conductivity type. In the following description, it is assumed that the first semiconductor layer 11 is an n type and the second semiconductor layer 12 is a p type.

The plurality of second stacked bodies SB2 extends in the third direction (the X-axis direction).

In this example, a direction from the first structured body B01 to the second structured body B02 is the third direction (the X-axis direction).

The connection portion CP (for example, the first connection portion 31) electrically connects at least one of the plurality of first semiconductor layers 11 and at least one of the plurality of second semiconductor layers 12 to each other.

In this example, a third structured body B03 and a fourth structured body B02 are provided. The third structured body B03 includes a plurality of third stacked bodies SB3. Each of the plurality of third stacked bodies SB3 includes a plurality of third semiconductor layers 13. The plurality of third semiconductor layer 13 are spaced from each other in the Z-axis direction.

A fourth structured body B04 includes a plurality of fourth stacked bodies SB4. Each of the plurality of fourth stacked bodies SB4 includes a plurality of fourth semiconductor layers 14. The plurality of fourth semiconductor layers 14 are spaced from each other in the Z-axis direction.

The plurality of third semiconductor layers 13 and the plurality of fourth semiconductor layers 14 extend in the second direction (the Y-axis direction). The plurality of third semiconductor layers 13 are the first conductivity type, and the plurality of fourth semiconductor layers 14 are the second conductivity type.

The plurality of third stacked bodies SB3 and the plurality of fourth stacked bodies SB4 are spaced from each other in the third direction (the X-axis direction).

The second connection portion 32 electrically connects at least one of the plurality of second semiconductor layers 12 and at least one of the plurality of third semiconductor layers 13 to each other. The third connection portion 33 electrically connects at least one of the plurality of third semiconductor layers 13 and at least one of the plurality of fourth semiconductor layers 14 to each other.

In this manner, in the thermoelectric conversion device 130, the plurality of semiconductor layers, for example, ha a line shape (or a stripe shape) extending in the Y-axis direction when viewed from the Z-direction. Semiconductor layers of the line shape are spaced apart in the Z-axis direction, and thus one stacked body is formed. A plurality of such stacked bodies are spaced from each other in the X-axis direction.

For example, a temperature difference is provided between one end, of the structured body in the Y-axis direction and the opposite end of the structured body in the Y-axis direction. Accordingly, a current flows through the semiconductor layer. Thermoelectric conversion is performed.

In the thermoelectric conversion device 130, because the semiconductor layers are stacked on top of one another, the power (at least any one of a current and a voltage) that is obtained per unit area is large. Additionally, the plurality of semiconductor layers of the line shape are separated in the X-axis direction from each other. Accordingly, the heat resistance is high. A reduction in the temperature difference that results from heat conduction can be suppressed, and an output with high efficiency of thermoelectric conversion per unit area is obtained. According to the present embodiment, a thermoelectric conversion device that can improve an output per unit area can be provided.

The length in the Y-axis direction, of a one of the plurality of semiconductor layers (the first to fourth semiconductor layers 11 to 14, and the like) is longer than the length in the X-axis direction, of the one of the plurality of semiconductor layers. The length in the Y-axis direction, of a one of the plurality of semiconductor layers is longer than a length in the Z-axis direction, of the one of the plurality of semiconductor layers. The length in the Y-axis direction, of one of the plurality of semiconductor layers, for example, is equal to or greater than 100 nm and is equal to or smaller than 10 cm. The length in the X-axis direction, of one of the plurality of semiconductor layers is, for example, equal to or greater than 10 nm and is equal to or smaller than 1 cm nm. The length in the Z-axis direction, of one of the plurality of semiconductor layers is, for example, equal to or greater than 10 nm and is equal to or smaller than 1000 nm.

The distance in the X-axis direction between one of the plurality of semiconductor layers (the first to fourth semiconductor layers 11 to 14 and the like) and another one of the plurality of semiconductor layers, for example, is 0.2 or more times, but 3 or less times the length thereof in the X-axis direction, of one of the plurality of semiconductor layers. A distance in the Z-axis direction between one of the plurality of semiconductor layers and another one of the plurality of semiconductor layers, for example, is 0.2 or more times, but 3 or less times the length in the Z-axis direction, of one of the plurality of semiconductor layers.

For example, using the process described with reference to FIGS. 3A and 3B, the thermoelectric conversion device 130 can be formed using the self-organization film having a stripe shape. Furthermore, the thermoelectric conversion device 130 can be formed by an exposure that uses a suitable mask.

As illustrated in FIG. 20B and FIGS. 21A and 21B, in the example, the interlayer insulating layer (each of the first to fourth interlayer insulating layers IL1 to IL4) is provided between each of the plurality of semiconductor layers (each of the first to fourth semiconductor layers 11 to 14). At least one interlayer insulating layer may be omitted.

Also in the thermoelectric conversion device 130, the base body 50s that has the surface 50a may be provided. The stacked body (for example, the first stacked body SB1) is provided on the surface 50a. The first direction described above intersects the surface 50a.

### Fourth Embodiment

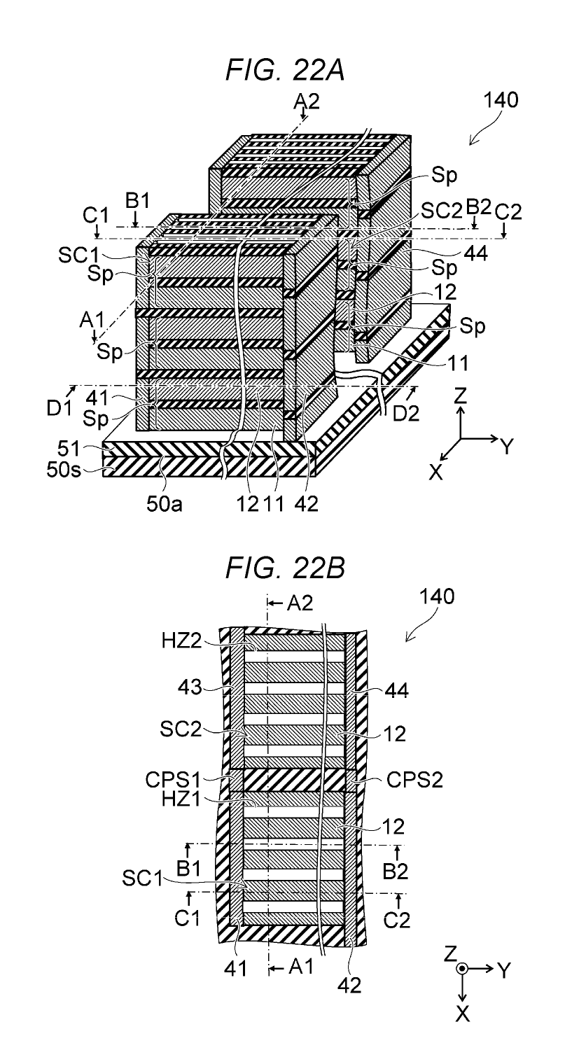

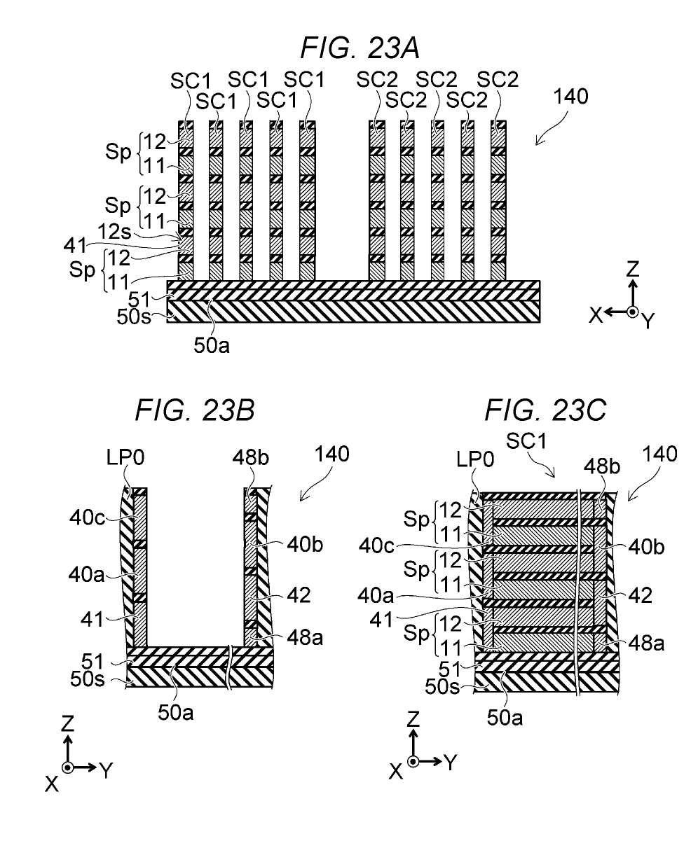

FIGS. 22A, 22B, and FIGS. 23A to 23C are schematic views illustrating a thermoelectric conversion device according to a fourth embodiment.

FIG. 22A is a perspective view. In FIG. 22A, some constituent elements are omitted. FIG. 22B is a sectional view taken along line D1-D2 in FIG. 22A. FIG. 23A is a sectional view taken along line A1-A2 in FIGS. 22A and 22B. FIG. 23B is a sectional view taken along line B1-B2 in FIGS. 22A and 22B. FIG. 23C is a sectional view taken along line C1-C2 in FIGS. 22A and 22B.

As illustrated in FIGS. 22A and 22B, a thermoelectric conversion device 140 according to the present embodiment includes the plurality of stacked bodies (for example, a plurality of first stacked bodies SC1 and the like), the first connection portion 41, and the second connection portion 42. The plurality of first stacked bodies SC1 is an example of the plurality of stacked bodies. In addition to the first stacked body SC1, a second stacked body SC2 may be provided.

The plurality of first stacked bodies SC1 (the plurality of stacked bodies) include the plurality of stacked portions Sp. The plurality of stacked portion Sp are spaced apart in the first direction (the Z-axis direction in the example).

As illustrated in FIG. 23A, one of the plurality of stacked portions Sp includes the first semiconductor layer 11 that has the first conductivity type, and the second semiconductor layer 12 that has the second conductivity type. The second semiconductor layer 12 is spaced from the first semiconductor layer 11 in the first direction (the Z-axis direction). The first semiconductor layer 11 and the second semiconductor layer 12 extend in the second direction. The second direction intersects the first direction. In this example, the second direction is the Y-axis direction.

The plurality of stacked bodies (for example, the plurality of first stacked bodies SC1) are spaced from each other in the third direction. The third direction intersects the first direction and the second direction. In this example, the third direction is the X-axis direction.

As illustrated in FIGS. 23A and 23C, the first connection portion 41 electrically connects the first semiconductor layer 11 included in one of the plurality of stacked portions Sp and the second semiconductor layer 12 included in the same one of the plurality of stacked portions Sp, to each other.

The second connection portion 42 electrically connects the second semiconductor layer 12 included in one of the plurality of stacked portions Sp and the first semiconductor layer 11 included in another one of the plurality of stacked portions Sp, to each other.

For example, in one first stacked body SC1, the connection portions, such as the first connection portion 41, the second connection portion 42, the connection portion 40a, the connection portion 40b, and the connection portion 40c, connect the first semiconductor layer 11 and the second semiconductor layer 12 are connected to each other in series.

In this example, the first terminal 48a and the second terminal 48b are provided. The first terminal 48a is electrically connected to the semiconductor layer (the first semiconductor layer 11 in this example) of one stacked portion at the other end of the first stacked body SC1. The second terminal 48b is electrically connected to the semiconductor layer (the second semiconductor layer 12 in the example) of a different stacked portion Sp at the other end of the first stacked body SC1. A current flows between the first terminal 48a and the second terminal 48b when a load is applied thereacross.

In the thermoelectric conversion device 140, because the semiconductor layers are stacked on top of one another, the power (at least any one of a current and a voltage) that is obtained per unit area is large. Additionally, the plurality of semiconductor layers of the line shape are spaced from each other in the X-axis direction. Accordingly, the heat resistance is high. A reduction in the temperature difference that results from the heat conduction can be suppressed, and a high thermoelectric conversion output is obtained. According to the present embodiment, a thermoelectric conversion device that can improve an output per unit area can be provided.

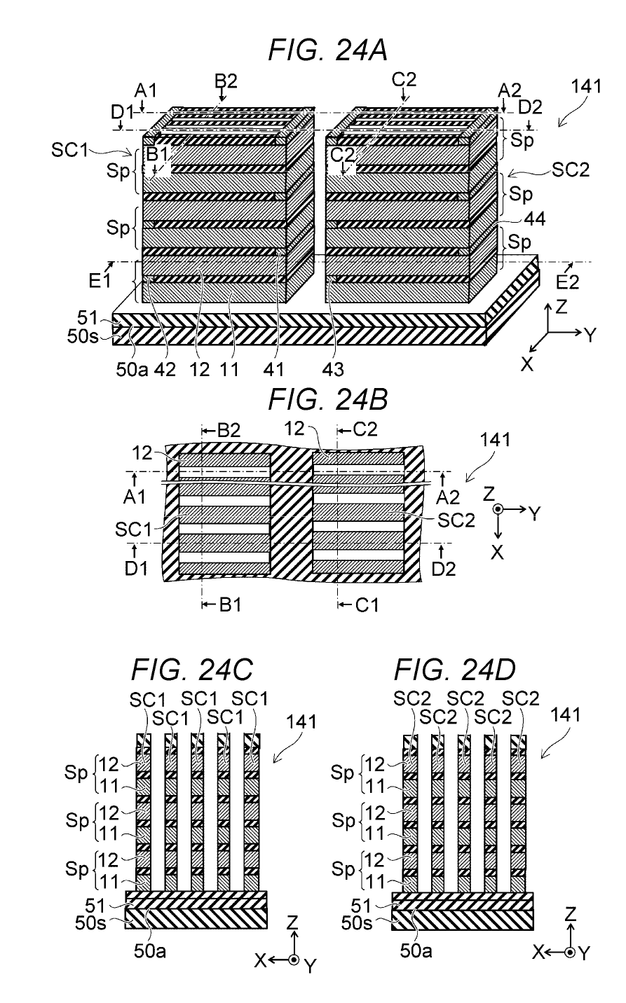

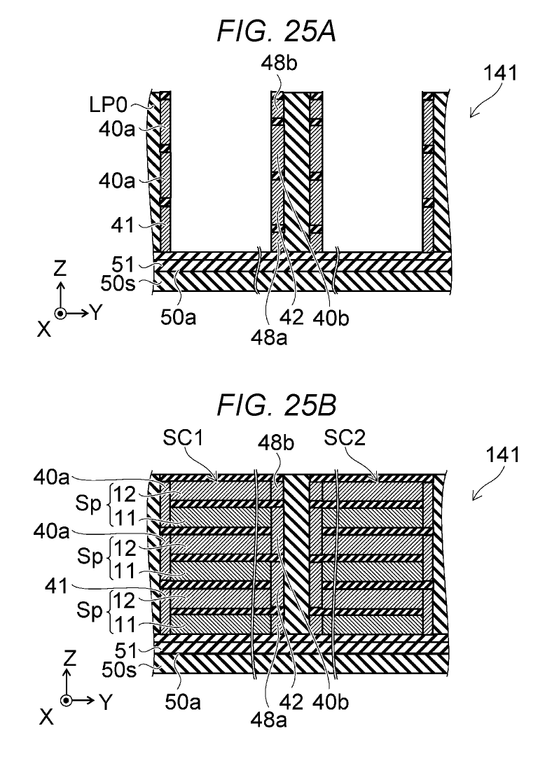

FIGS. 24A to 24D and FIGS. 25A and 25B are schematic views illustrating another thermoelectric conversion device according to the fourth embodiment.

FIG. 24A is a perspective view. In FIG. 24A, some constituent elements are omitted. FIG. 24B is a sectional view taken along line E1-E2 in FIG. 24A. FIG. 24C is a sectional view taken along line B1-B2 in FIGS. 24A and 24B. FIG. 24D is a sectional view taken along line C1-C2 in FIGS. 24A and 24B. FIG. 25A is a sectional view taken along line A1-A2 in FIGS. 24A and 24B. FIG. 25B is a sectional view taken along line D1-D2 in FIGS. 24A and 24B.

As illustrated in FIGS. 24A and 24B, a thermoelectric conversion device 141 according to the present embodiment includes the plurality of stacked bodies (for example, the plurality of first stacked bodies SC1 and the like), the first connection portion 41, and the second connection portion 42. The plurality of first stacked bodies SC1 is an example of the plurality of stacked bodies. In addition to the first stacked body SC1, the second stacked body SC2 may be provided.

The plurality of first stacked bodies SC1 (the plurality of stacked bodies) include the plurality of stacked portions Sp. A configuration of the plurality of stacked portions Sp is the same as that of the thermoelectric conversion device 140.

In a thermoelectric conversion device 141 according to the present embodiment, the connection portion is provided between two semiconductor layers. For example, the first connection portion 41 electrically connects the first semiconductor layer 11 of one of the plurality of stacked portions Sp and the second semiconductor layer 12 of the same one of the plurality of stacked portions Sp to each other.

Additionally, the second connection portion 42 electrically connects the second semiconductor layer 12 of one of the plurality of stacked portions Sp and the first semiconductor layer 11 of another one of the plurality of stacked portions Sp, to each other. At least one part of the second connection portion 42 electrically connects between the second semiconductor layer 12 of one of the plurality of stacked portions Sp and the first semiconductor layer 11 of another one of the plurality of stacked portions Sp.

In this example, substantially the entirety of one connection portion is provided between two semiconductor layers at adjacent ends thereof.

In the thermoelectric conversion device 141, an area that is occupied by one stacked body can be decreased. For example, in the case where the plurality of stacked bodies are provided on a substrate, the distance between each of the plurality of stacked bodies can be reduced. Accordingly, the power that is obtained per unit area can further be increased. Also in the thermoelectric conversion device 141, a thermoelectric conversion device that can improve an output per unit area can be provided.

Also in the thermoelectric conversion devices 140 and 141, the base body 50s that has the surface 50a may be provided. The stacked body (for example, the first stacked body SC1) is provided on the surface 50a. The first direction described above intersects the surface 50a.

### Fifth Embodiment

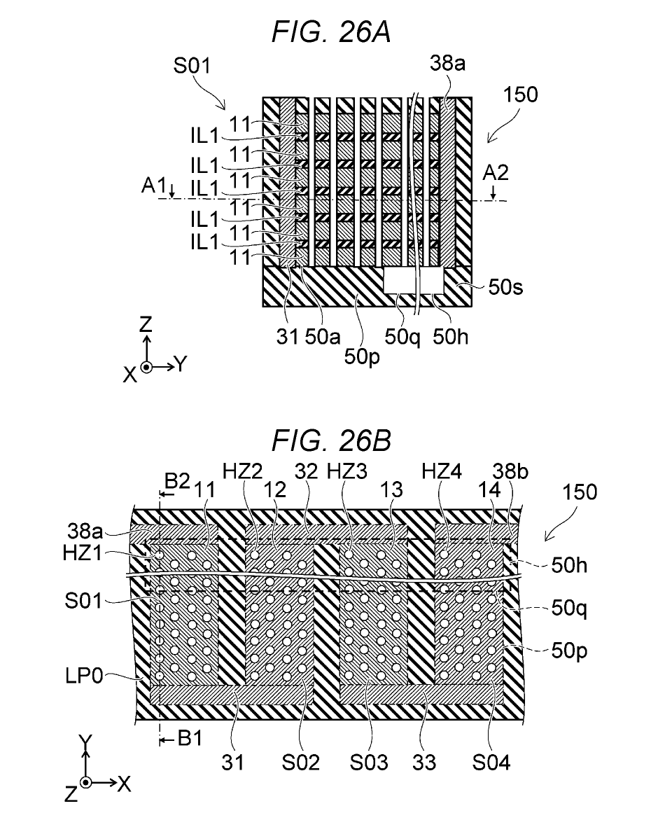

FIGS. 26A and 26B are schematic sectional views illustrating a thermoelectric conversion device according to a fifth embodiment.

FIG. 26A is a sectional view taken along line B1 to B2 in FIG. 26B. FIG. 26B is a sectional view taken along line A1 to A2 in FIG. 26A.

As illustrated in FIGS. 26A and 26B, a thermoelectric conversion device 150 according to the present embodiment includes the first stacked body S01, the second stacked body S02, the first connection portion 31, and the base body 50s. The first stacked body S01, the second stacked body S02, and the first connection portion 31 are the same as those of the thermoelectric conversion device 110, and thus descriptions thereof are omitted.

A stacked body is provided on the surface 50a of the base body 50s. The base body 50s includes a first region 50p and a second region 50q. For example, a material of the second region 50q is different from a material of the first region 50p. For example, the density of the second region 50q is lower than the density of the first region 50p. For example, the second region 50q includes a cavity 50h, and the first region 50p does not include the cavity 50h. For example, the thickness of the second region 50q is greater than that of the first region 50p. The thickness is a length in the direction substantially perpendicular to the surface 50a. For example, thermal conductivity of the material of the second region 50q is lower than thermal conductivity of the material of the first region 50p. The second region 50q may be a recess (or a hole) provided on the base body 50s.

The direction connecting the first region 50p and the second region 50q to each other intersects the first direction (the Z-axis direction). In this example, the direction connecting the first region 50p and the second region 50q is in the Y-axis direction.

For example, in a case where the first connection portion 31 and the first terminal 38a, which are already described, are provided, the direction between the first region 50p and the second region 50q is in the direction extending between the first connection portion 31 and the first terminal 38a. For example, in a case where the first connection portion 31 and the second connection portion 32 are provided, the direction between the first region 50p and the second region 50q is in the direction extending between the first connection portion 31 and the second connection portion 32.

In the Z-axis direction, the stacked body (for example, the first stacked body S01, the second stacked body S02, and the like) overlies the first region 50p. For example, in the Z-axis direction, at least one portion of the second region 50q may underlie at least any one of the first terminal 38a and the second connection portion 32.

In the thermoelectric conversion device 150, for example, a region (for example, the second region 50q) that has lower thermal conductivity than other portions is provided in the base body 50s. Accordingly, the heat conduction in the base body 50s is reduced. For example, a temperature difference between a high temperature portion and a low temperature portion can be better maintained. Thus a thermoelectric conversion device 150 that can improve the output per unit area can be provided.

For example, in the thermoelectric conversion device 150, the heat conduction from the substrate side to the semiconductor layer is reduced. For example, in the thermoelectric conversion device 150, the temperature rise on the low temperature side of the device can be suppressed. The output per unit area can be improved.

An example of a method of manufacturing the thermoelectric conversion device 150 will be described below.

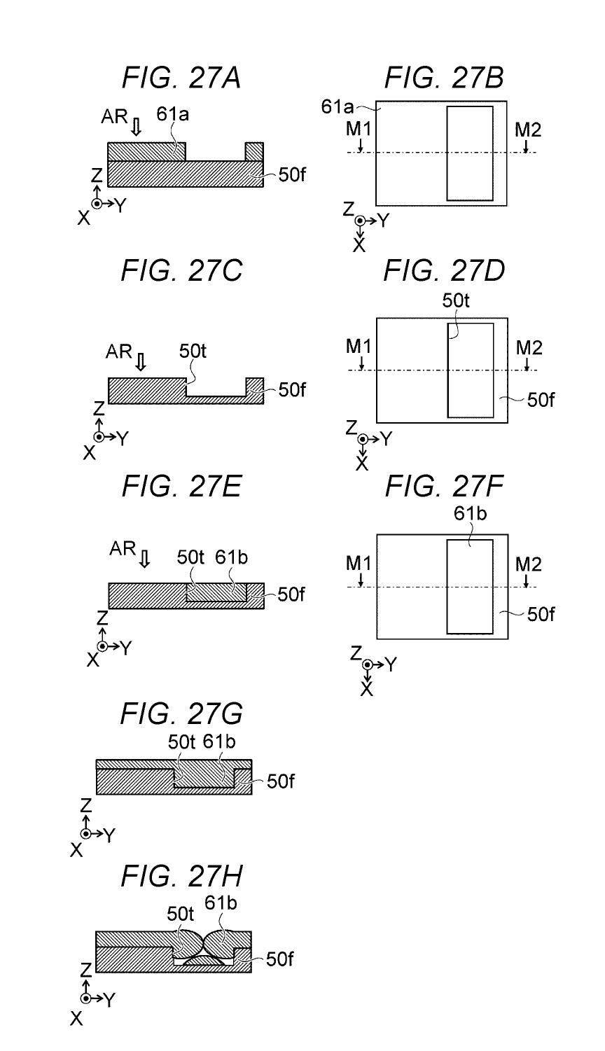

FIGS. 27A to 27H, FIGS. 28A to 28J, and FIGS. 29A to 29J are schematic views illustrating the method of manufacturing the thermoelectric conversion device according to the fifth embodiment.

FIGS. 27A, 27C, and 27E, FIGS. 28A, 28C, 28E, 28G, and 28I, and FIGS. 29A, 29C, 29E, 29G, and 29I are sectional views taken along line M1-M2 in FIGS. 27B, 27D, and 27F, FIGS. 28B, 28D, 28F, 28H, and 28J, and FIGS. 29B, 29D, 29F, 29H, and 29J, respectively. FIGS. 27G and 27H are sectional views that correspond to line M1-M2 of FIG. 27F. FIGS. 27B, 27D, and 27F, FIGS. 28B, 28D, 28F, 28H, and 28J, and FIGS. 29B, 29D, 29F, 29H, and 29J are plan views when viewed in the direction of arrow AR illustrated in FIGS. 27A, 27C, and 27E, FIGS. 28A, 28C, 28E, 28G, and 28I, and FIGS. 29A, 29C, 29E, 29G, and 29I, respectively.

As illustrated in FIGS. 27A and 27B, a resist pattern 61a is formed on a substrate 50f. The resist pattern 61a is formed using lithography. The substrate 50f is, for example, a silicon substrate.

As illustrated in FIGS. 27C and 27D, the substrate 50f is processed using the resist pattern 61a as a mask, for example, using RIE. Accordingly, a groove 50t is formed. The depth of the groove 50t, for example, is 10 μm.

As illustrated in FIGS. 27E and 27F, an intermediate member 61b is buried into the groove 50t. The intermediate member 61b, for example, is made of organic material. The intermediate member 61b, for example, is formed into the groove 50t, using spin coating. Adjustment of a condition for the spin coating causes the height of the upper surface of the intermediate member 61b to be substantially the same as the height of the upper surface of the substrate 50f.

As illustrated in FIG. 27G, the intermediate member 61b may be provided on the entire upper surface of the substrate 50f. Thereafter, for example, the performing of the etching-back or a CMP process will cause the height of the upper surface of the intermediate member 61b to be substantially the same as the height of the upper surface of the substrate 50f, and the formation of the intermediate member 61b, for example, may be formed using CVD.

As illustrated in FIG. 27H, a gap may occur between the intermediate member 61b and the groove 50t.

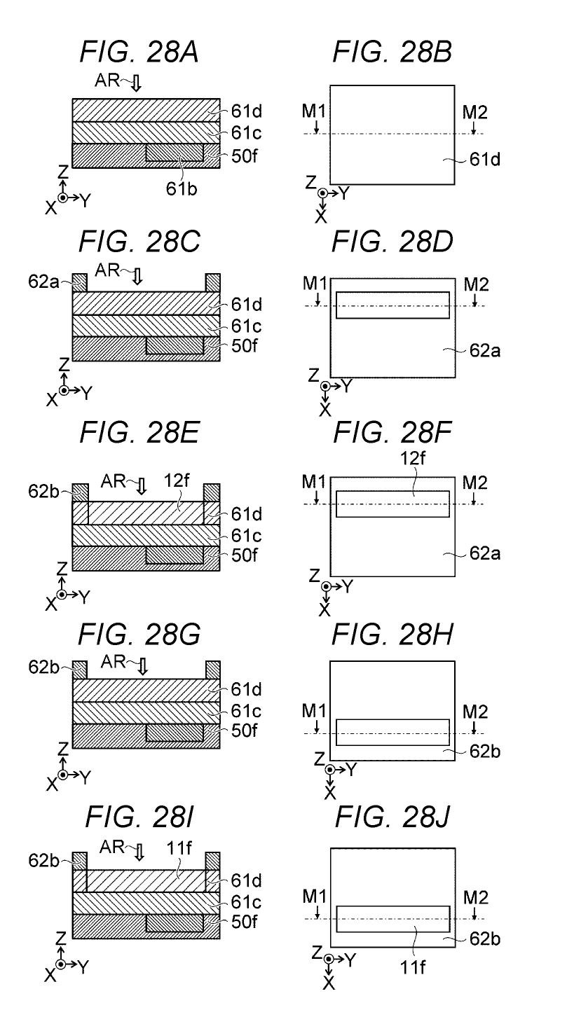

As illustrated in FIGS. 28A and 28B, a silicon oxide film 61c is formed, and polysilicon film 61d is formed on the silicon oxide film 61c. The thickness of the silicon oxide film 61c, for example, is approximately 100 nm. The thickness of the polysilicon film 61d is approximately 100 nm. These films, for example, are formed using CVD. One silicon oxide film 61c and one polysilicon film 61d are illustrated in these figures. A plurality of silicon oxide films 61c and a plurality of polysilicon films 61d may be alternately formed.

As illustrated in FIGS. 28C and 28D, a resist 62a that has an opening is formed.

As illustrated in FIGS. 28E and 28F, for example, impurities that are the second conductivity type are implanted using ion implantation. Accordingly, a second semiconductor film 12f that has the second conductivity type is formed. Thereafter, the resist 62a is removed.

As illustrated in FIGS. 28G and 28H, a resist 62b that has an opening is formed. A position of the opening in the resist 62b is different from a position of the opening in the resist 62a.

As illustrated in FIGS. 28I and 28J, for example, impurities that are the first conductivity type are implanted using ion implantation. Accordingly, a first semiconductor film 11f that has the first conductivity type is formed.

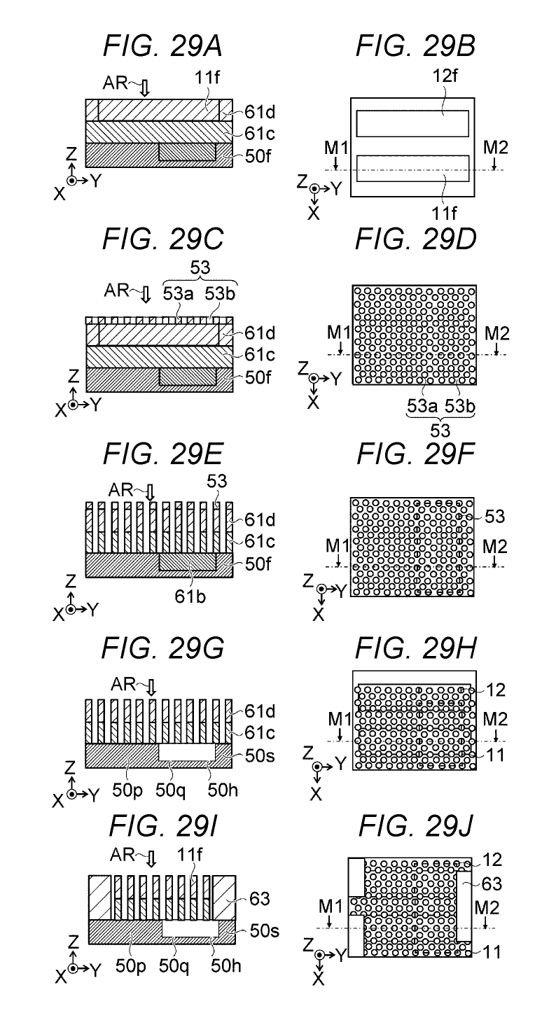

As illustrated in FIGS. 29A and 29B, the resist 62b is removed.

As illustrated in FIGS. 29C and 29D, the block copolymer film 53 is formed. The block copolymer 53 includes a styrene containing portion (for example, PS) and an acrylic containing portion (for example, PMMA). A ratio of PS to PMMA is, for example, 7/3. A molecular weight of the block copolymer 53, for example, is 100 k. Accordingly, the block copolymer 53 that is PS-b-PMMA is obtained. A film of the block copolymer 53, for example, is formed using the spin coating. The thickness of the formed film is approximately 50 nm. For example, annealing is performed at a temperature of 240° C. for 180 seconds. Accordingly, phase separation occurs, and thus, the fine pattern is obtained by self-organization. The self-organized film, for example, includes the plurality of first film portions 53a and the second film portion 53b. Each of the plurality of first film portions 53a extends in the Z-axis direction. The size (the length in one direction along the X-Y plane) of one of the plurality of first film portions 53a is approximately 20 nm. The cylinder-shaped structure is completed. The plurality of first film portions 53a are, for example, arranged in a substantially hexagonal pattern.

For example, UV light is emitted to the self-organization film (the film of the block copolymer 53). Accordingly, a side chain of a PMMA cylinder is cut off. Thereafter, for example, the wet etching is performed using alcohol (isopropyl alcohol or the like). Accordingly, the PMMA cylinder is removed. Accordingly, an opening (a hole pattern) is formed in the self-organized film (the film of the block copolymer 53). A size (width) of the opening is approximately 20 nm.

As illustrated in FIGS. 29E and 29F, one portion of each of the semiconductor film (the first semiconductor film 11f and the second semiconductor film 12f) and the silicon oxide film 61c is removed using the self-organization film (the film of the block copolymer 53), in which the opening is formed, as a mask. Accordingly, an opening is formed in the semiconductor film (the first semiconductor film 11f and the second semiconductor film 12f) and the silicon oxide film 61c. The intermediate member 61b is exposed in the opening.

As illustrated in FIGS. 29G and 29H, the intermediate member 61b is removed. For example, an ashing process that uses oxygen plasma is performed. Accordingly, via the opening, the intermediate member 61b is removed. Accordingly, the cavity 50h is formed. Accordingly, the base body 50s is obtained that includes the first region 50p and the second region 50q. The first semiconductor layer 11 is obtained from the first semiconductor film 11f. The second semiconductor layer 12 is obtained from the second semiconductor film 12f.

As illustrated in FIGS. 29I and 29J, an interconnection portion 63 is formed. The interconnection portion 63 electrically connects the first semiconductor layer 11 and the second semiconductor layer 12 to each other. The interconnection portion 63, for example, corresponds to the connection portion. The interconnection portion 63, for example, contains metal such as tungsten.

In the process described above, after forming a groove for the formation of the interconnection portion 63, the intermediate member 61b is removed via at least one portion of the groove, and the opening. The removal is easily performed.

The base body 50s that includes the first region 50p and the second region 50q can be applied to the thermoelectric conversion device according to the first to fourth embodiments, and to a thermoelectric conversion device that is a modification thereto.

In the manufacturing method described above, in addition to the method that uses the self-organization film, at least any one of photolithography that uses light, EUV lithography, nanoimprint, and EB drawing can apply to the formation of the fine pattern.

According to the present embodiment, for example, in the base body 50s, a region (the second region 50q) that has a different thermal conductivity than other regions (the first region 50p) is provided positioned under an electrode (for example, the connection portion) on the low temperature side of the device. At least one portion of a border between two regions that have different thermal conductivity overlaps the first semiconductor layer 11 and the second semiconductor layer 12 in the Z-axis direction.

In a case where the first stacked body S01 and the second stacked body S02 (refer to FIG. 1B) are provided, the second region 50q, for example, overlaps the first stacked body S01 and the second stacked body S02 in the Z-axis direction. An area along a X-Y plane of the second region 50q may be larger than an area of these stacked bodies. The second region 50q may include a plurality of layers and at least two materials of the plurality of layers may be different from each other.

The manufacturing method described above includes a process of forming a groove in a substrate, a process of burying material into the groove, a process of forming an insulating film, a process of forming polysilicon, a process of forming a fine pattern on the polysilicon, a process of pattern-transferring the fine pattern to the polysilicon and the insulating film, and a process of selectively removing the buried material after the pattern transferring. For example, the burying material may contain an organic material. The burying of the burying material, for example, may be performed using spin coating. The burying of the burying material may be performed using CVD. The operations of forming the fine pattern described above, for example, may include at least one operation that is selected from a group that consists of photolithography, EUV lithography, directed self-assembly (DSA), nanoimprint, and e-beam patterning. A size of the fine pattern described above, for example, is equal to or greater than 100 nm. The manufacturing method described above, for example, may further include a process of forming an interconnection after removing the burying material.

For example, a silicon thermoelectric conversion portion that has a fine pattern is formed on a supporting substrate. For example, when the supporting substrate is thickened, the thickness of the thermoelectric conversion relative to the thickness of the supporting substrate decreases, and an influence of the heat conduction on the supporting substrate increases. When the thermal conductivity of the supporting substrate is high, the temperature difference across the thermoelectric conversion portion decreases and the power that is obtained decreases. According to the embodiments described above, for example, heat conduction in the supporting substrate is suppressed. For example, a high thermoelectric conversion output is obtained.

### Sixth Embodiment

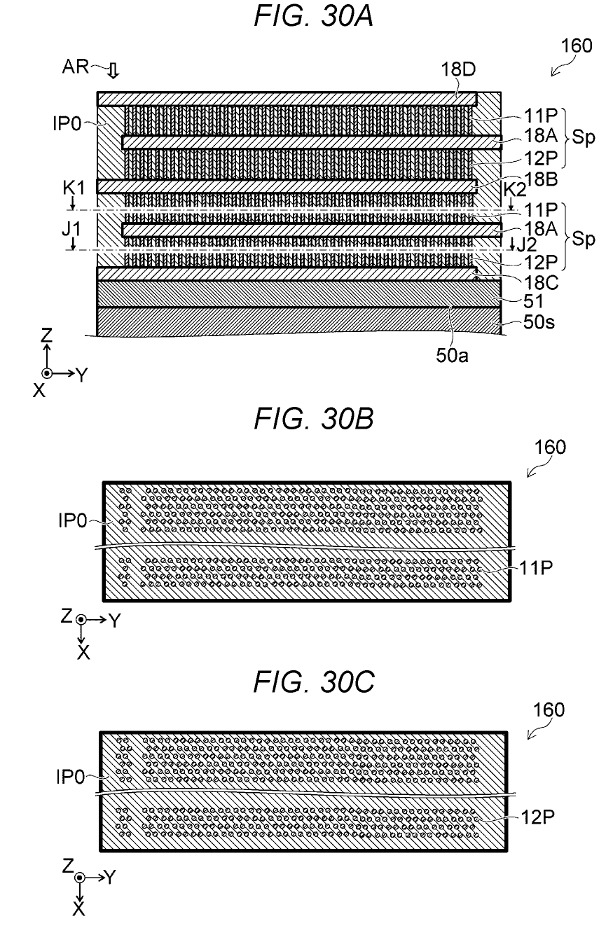

FIGS. 30A to 30C, FIGS. 31A and 31B, and FIGS. 32A to 32B are schematic diagrams illustrating a thermoelectric conversion device according to a sixth embodiment.

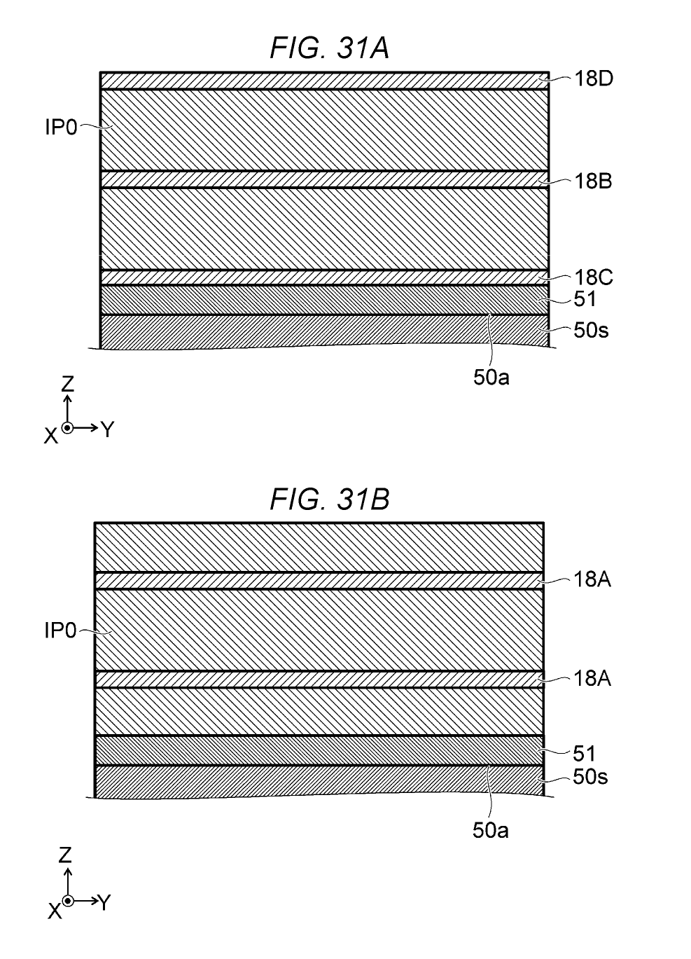

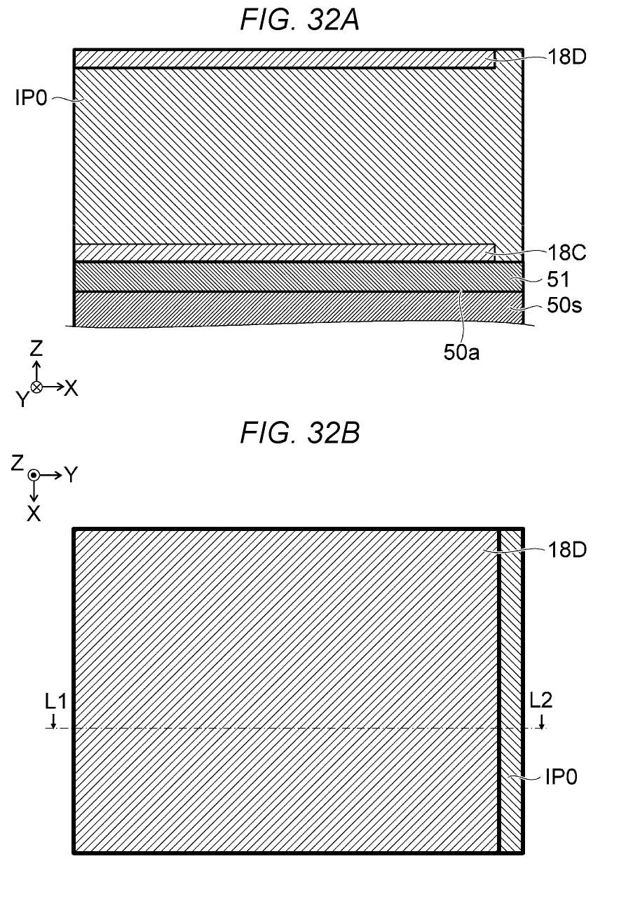

FIG. 30A is a sectional view taken along line L1 to L2 in FIG. 32B. FIG. 30B is a sectional view taken along line K1 to K2 in FIG. 30A. FIG. 30C is a sectional view taken along line J1 to J2 in FIG. 30A. FIGS. 31A and 31B and FIG. 32A are side-views. FIG. 32B is a top-view viewed in a direction of an arrow AR in FIG. 30A.

As illustrated in FIG. 30A, a thermoelectric conversion device 160 according to the present embodiment includes the plurality of stacked portions Sp. The plurality of stacked portion Sp are spaced apart from each other in the first direction (the Z-axis direction in the example).

One of the plurality of stacked portions Sp includes a plurality of first semiconductor portions 11P, a plurality of second semiconductor portions 12P, and a first conductive layer 18A. The plurality of first semiconductor portions 11P are the first conductivity type (for example, the n types), and the plurality of second semiconductor portions 12P are the second conductivity type (for example, the p type).

The plurality of the first semiconductor portions 11P are arranged along one plane (for example, the X-Y plane). The one plane intersects the first direction. The plurality of second semiconductor portions 12P are arranged along the one plane (for example, the X-Y plane). The plurality of second semiconductor portions 12P are separated, in the Z-axis direction, from the plurality of first semiconductor portions 11P.

One of the plurality of first semiconductor portions 11P (for example, each of the plurality of first semiconductor portions 11P) extends in the first direction. One of the plurality of second semiconductor portions 12P (for example, each of the plurality of second semiconductor portions 12P) extend in the first direction. These semiconductor portions have a columnar shape extending in the first direction.

The first conductive layer 18A is provided between the plurality of first semiconductor portions 11P and the plurality of second semiconductor portions 12P. The first conductive layer 18A electrically connects at least one or several of the plurality of first semiconductor portions 11P and at least one or several of the plurality of second semiconductor portions 12P to each other. The first conductive layer 18A electrically connects the plurality of first semiconductor portions 11P to each other. The first conductive layer 18A electrically connects the plurality of second semiconductor portions 12P to each other.

For example, a temperature difference is provided between one end in the Y-axis direction of the device and the other end of the device in the Y-axis direction. Accordingly, the number of carriers increases in one end (a high temperature portion) in the Y-axis direction, of the plurality of first semiconductor portions 11P. At least one or several of the carriers that occur in the plurality of first semiconductor portions 11P flow along the X-Y plane via the first conductive layer 18A. On the other hand, the number of carriers increases also in one end (a high temperature portion) in the Y-axis direction, of the plurality of second semiconductor portions 12P. At least one or several of the carriers that occur in the plurality of second semiconductor portions 12P flow along the X-Y plane via the first conductive layer 18A. The flow of these carriers results in current. The current flows out when the device is connected across a load. In this manner, the thermoelectric conversion is performed.

According to the embodiment, for example, groups of semiconductor portions having the columnar shape are stacked with the first conductive layer 18A in between them. The plurality of first semiconductor portions 11P are separated from each other. The plurality of second semiconductor portions 12P are also separated from each other. Accordingly, a heat resistance in the direction of the X-Y plane can increase. A reduction in temperature difference due to the heat conduction can be suppressed. According to the embodiment, the thermoelectric conversion device that can improve an output per unit area can be provided.

In the thermoelectric conversion device 160, the plurality of stacked portions Sp are provided. Accordingly, a current (an electric power) that is obtained per unit area can be increased. The thermoelectric conversion device that can improve an output per unit area can be provided.

In this example, the thermoelectric conversion device 160 includes a second conductive layer 18B, a third conductive layer 18C, and a fourth conductive layer 18D.

The second conductive layer 18B is provided between stacked portions Sp. The second conductive layer 18B electrically connects at least one first semiconductor portion 11P that is included in one of the plurality of stacked portions Sp, and at least one second semiconductor portion 12P that is included in another one of the plurality of stacked portions Sp, to each other. Furthermore, the second conductive layer 18B electrically connects at least one second semiconductor portion 12P that is included in one of the plurality of stacked portions Sp, and at least one first semiconductor portion 11P that is included in another one of the plurality of stacked portions Sp, to each other.

The fourth conductive layer 18D is separated from the third conductive layer 18C in the first direction (the Z-axis direction). The plurality of stacked portions Sp and the second conductive layer 18B, which are described above, are provided between the third conductive layer 18C and the fourth conductive layer 18D. The third conductive layer 18C and the fourth conductive layer 18D result in output terminals for the current.

For example, a plurality of conductive layers are spaced apart in the Z-axis direction, and a semiconductor portion is provided between each of the plurality of conductive layers. The conductivity types of these semiconductor layers alternately change.

According to the embodiment, a length in the first direction of the plurality of semiconductor portions (the first semiconductor portion 11P and the second semiconductor portion 12P) is longer than the width of the semiconductor portions 11P, 12P. The width is a distance in a direction (for example, the Y-axis direction) perpendicular to the first direction.

A width (for example, a distance in the Y-axis direction) of one of the plurality of semiconductor portions (the first semiconductor portions 11P and the second semiconductor portion 12P) is equal to or greater than 10 nm and is equal to or smaller than 300 nm. A distance (the shortest distance) between two of the plurality of semiconductor portions (the first semiconductor portion 11P and the second semiconductor portion 12P), for example, is 0.1 or more times, but 1.5 or less times the width described above. For example, this distance is equal to or greater than 3 nm and is equal to or smaller than 15 nm.

A length (a length along the first direction) of one of the plurality of semiconductor portions (the first semiconductor portions 11P and the second semiconductor portions 12P), for example, is equal to or greater than 0.5 μm and is equal to or smaller than 10 μm. The length, for example, may be equal to or greater 2 μm and is equal to or smaller than 5 μm. The length, for example, is approximately equal to or smaller than 4 μm.

The plurality of semiconductor portions, for example, contain polysilicon. The plurality of semiconductor portions, for example, may contain germanium. The plurality of semiconductor portions may include Bi and Te.

The thickness (a length along the first direction) of one of the conductive layers (the first conductive layer 18A, the second conductive layer 18B, the third conductive layer 18C, the fourth conductive layer 18D, and the like) described above, for example, is equal to or greater than 50 μm and is equal to or smaller than 200 μm. The conductive layer described above, for example, contains metal (tungsten or the like). The conductive layer described above, for example, may function as an electrode.

The thermoelectric conversion device 160 may include the base body 50s. The semiconductor portion and the conductive layer, which are described above, are provided on the surface 50a of the base body 50s. The base bodies 50s, for example, include a silicon substrate. When it comes to the base body 50s, the insulating layer 51 is provided between the base body 50s and the third conductive layer 18C. The insulating layer 51, for example, contains silicon nitride. The thickness of the insulating layer 51, for example, is approximately 1 μm. A length in the Y-axis direction, of the base body 50s, for example, is approximately 20 mm.

In this example, the insulating portion LP0 is provided around the plurality of semiconductor portions. The insulating portion LP0 may cover one portion of the conductive layer. As will be described below, at least one portion of the insulating portion LP0 may be omitted. As shown in FIG. 30A, the insulating portion LP0 may have a portion that overlaps the first conductive layer 18A in the Y-axis direction. A length in the Y-axis direction, of the overlapping portion, for example, is 5 mm.

An example of a method of manufacturing the thermoelectric conversion device 160 will be described below.

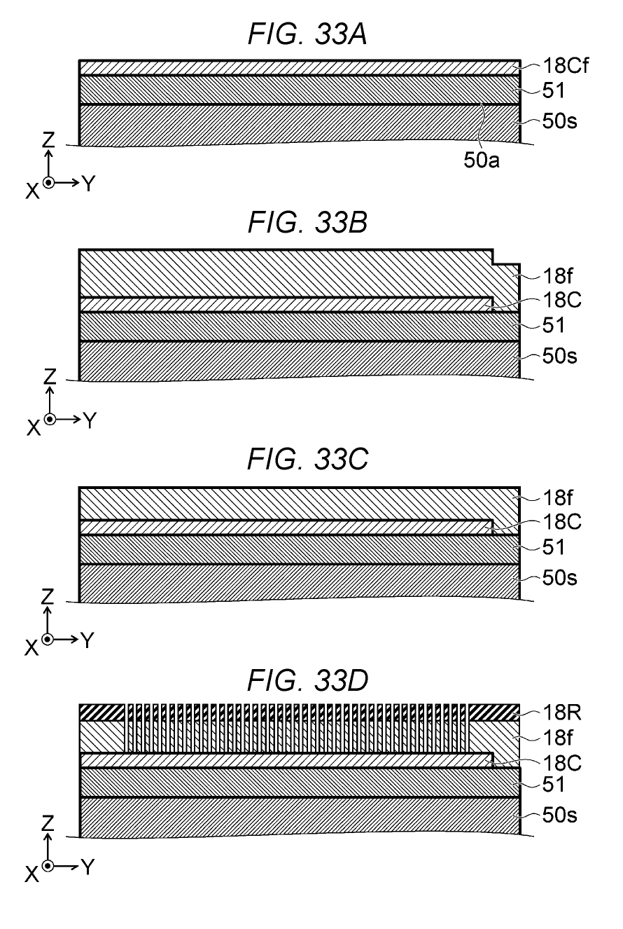

FIGS. 33A to 33D, FIGS. 34A to 34D, and FIGS. 35A to 35C are schematic sectional views in the order of processes, each illustrating a result of steps in the method of manufacturing the thermoelectric conversion device according to the sixth embodiment.

As illustrated in FIG. 33A, the insulating layer 51 (for example, a silicon nitride film) is formed on the surface 50a of the base body 50s (for example, a silicon substrate). A conductive film 18Cf (for example, a tungsten film) that results in the third conductive layer 18C is formed on the insulating layer 51.

As illustrated in FIG. 33B, one portion of the conductive film 18Cf is removed, and thus the third conductive layer 18C is formed. An insulating film 18f (for example, a silicon oxide film) is formed on the third conductive layer 18C.

As illustrated in FIG. 33C, a flattening process is performed.

As illustrated in FIG. 33D, a resist film 18R is formed. The resist film 18R has a plurality of openings. For formation of the openings, photolithography, EUV lithography, DSA, nanoimprint, electron beam patterning, or the like is used. Portions of the insulating film 18f are removed using the resist film 18R as a mask. Holes are formed in the insulating film 18f.

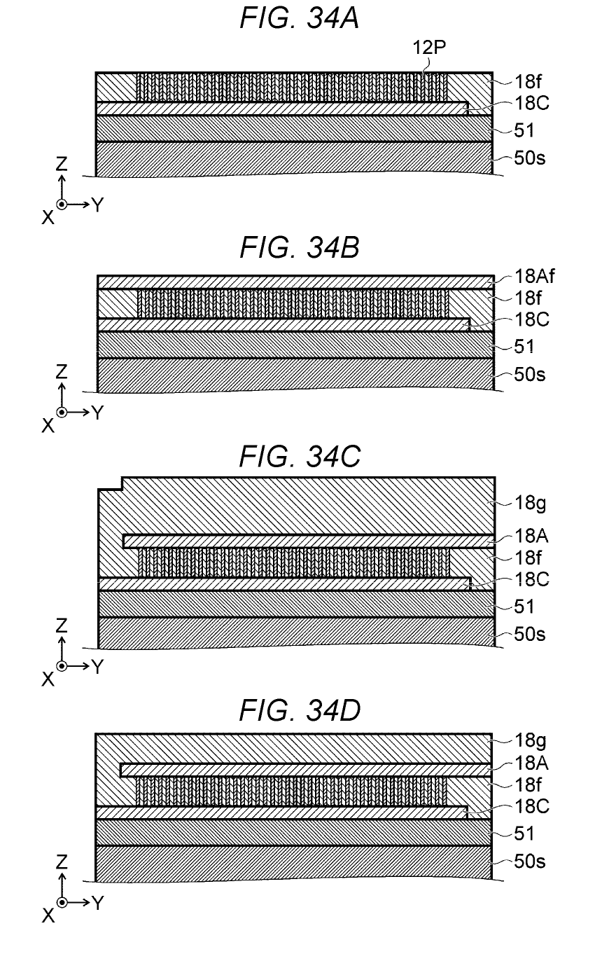

As illustrated in FIG. 34A, the semiconductor of the second conductivity type is buried into the holes in the insulating film 18f, and the flattering is performed. The semiconductor, for example, includes polysilicon. With the semiconductor, the second semiconductor portion 12P is formed.

As illustrated in FIG. 34B, a conductive film 18Af (for example, a tungsten film) that results in the first conductive layer 18A is formed.

As illustrated in FIG. 34C, one portion of the conductive film 18Af is removed, and thus the first conductive layer 18A is formed. An insulating film 18g (for example, a silicon oxide film) is formed on the first conductive layer 18A.

As illustrated in FIG. 34D, the flattening process is performed.

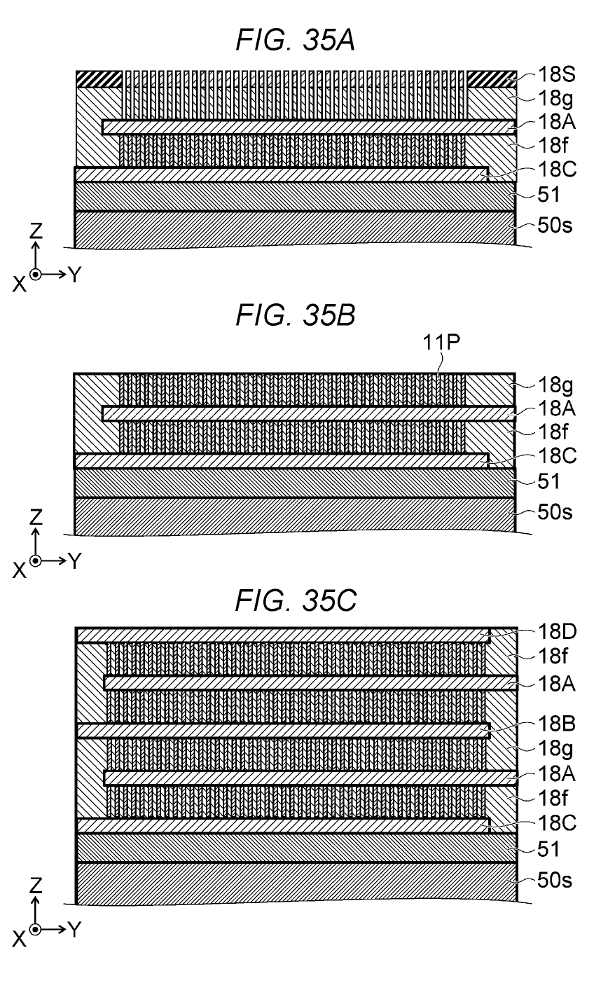

As illustrated in FIG. 35A, a resist film 18S is formed. For the formation of the resist film 18S, for example, a method that is the same as the method of forming the resist film 18R is used. Portions of the insulating film 18g is removed using the resist film 18R as a mask. Holes are formed in the insulating film 18g.

As illustrated in FIG. 35B, the semiconductor of the first conductivity type is buried into the hole in the insulating film 18g, and the flattening is performed. The semiconductor, for example, includes polysilicon. With the semiconductor, the first semiconductor portion 11P is formed.

As illustrated in FIG. 35C, the processes described above are repeated. Accordingly, the thermoelectric conversion device 160 is manufactured.

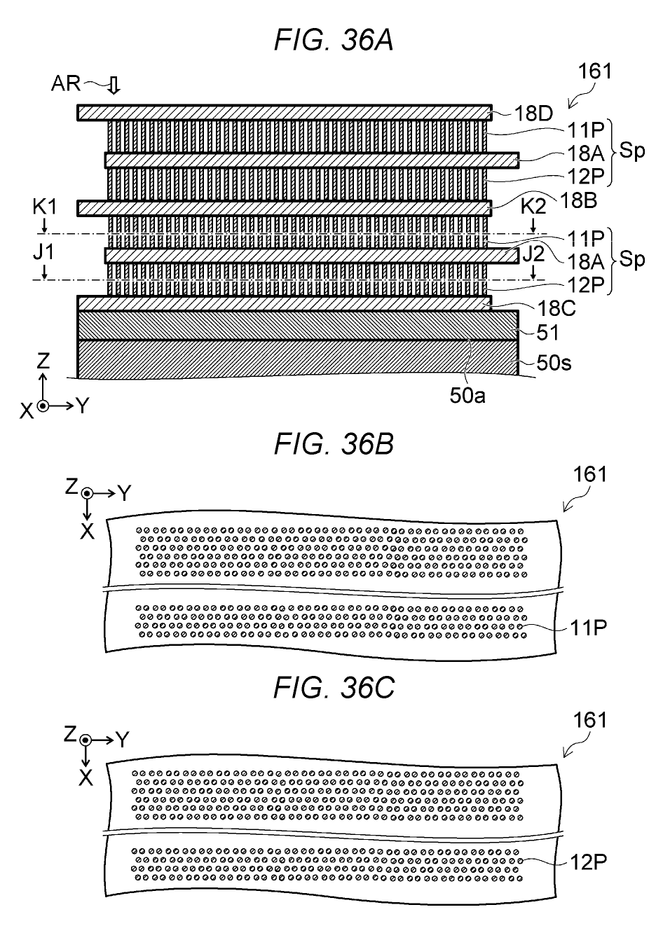

FIGS. 36A to 36C are schematic sectional view illustrating another thermoelectric conversion device according to the sixth embodiment.

FIG. 36B is a sectional view taken along line K1 to K2 in FIG. 36A. FIG. 36C is a sectional view taken along line J1 to J2 in FIG. 36A.

As illustrated in these figures, in a thermoelectric conversion device 161, the insulating portion LP0 is not provided. Except for this, thermoelectric conversion device 161 is the same as the thermoelectric conversion device 160.

In the method of manufacturing the thermoelectric conversion device 160, which is described above, the insulating films 18f and 18g and the like are removed after forming the semiconductor portion. Accordingly, the thermoelectric conversion device 161 can be manufactured.

In the thermoelectric conversion device 161 a region between each of the plurality of first semiconductor portions 11P is a cavity. A region between each of the plurality of second semiconductor portions 12P is a cavity. Accordingly, for example, the heat conduction can be suppressed between a conductive film 18A and a conductive film 18B. A temperature difference can be kept great. Also in the thermoelectric conversion device 161, a thermoelectric conversion device that can improve an output per unit area can be provided. In the cavity, for example, gas (air) is present.

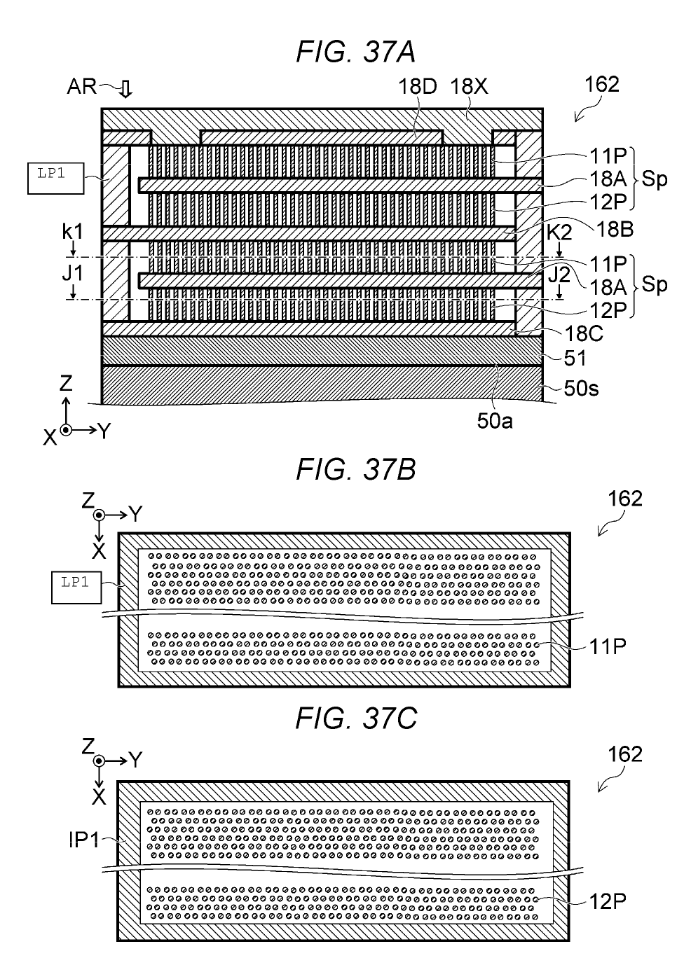

FIGS. 37A to 37C, FIGS. 38A and 38B, and FIGS. 39A to 39B are schematic views illustrating another thermoelectric conversion device according to the sixth embodiment.

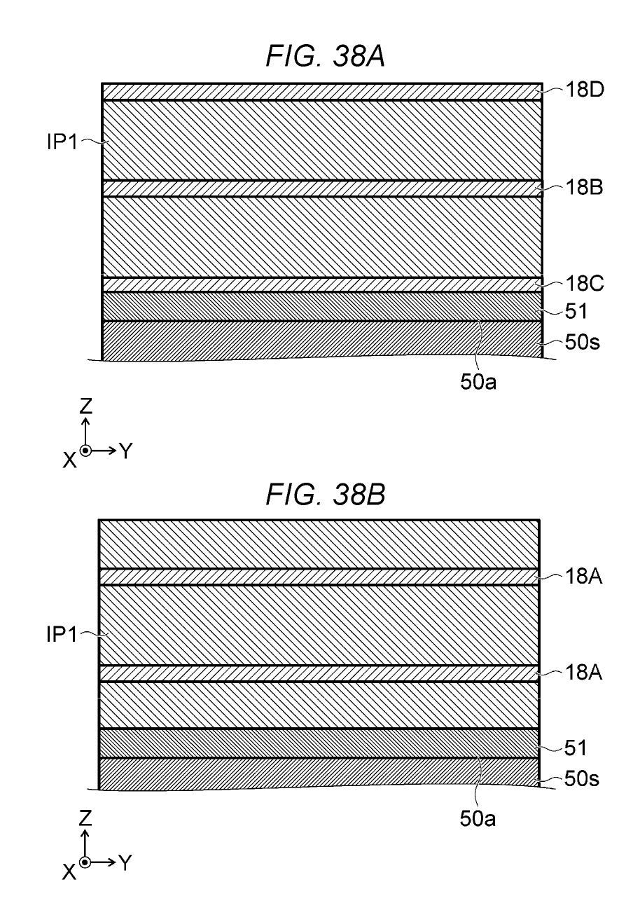

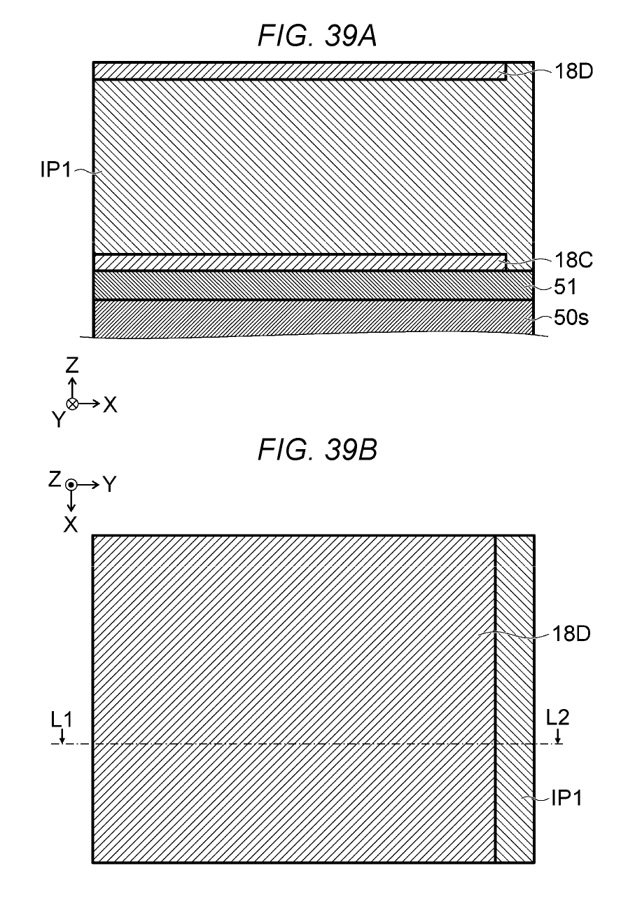

FIG. 37A is a sectional view taken along line L1 to L2 in FIG. 39B. FIG. 37B is a sectional view taken along line K1 to K2 in FIG. 37A. FIG. 37C is a sectional view taken along line J1 to J2 in FIG. 37A. FIGS. 38A and 38B and FIG. 39A are side-views. FIG. 39B is a plan-view when viewed in a direction of an arrow AR in FIG. 37A.

As illustrated in these figures, another thermoelectric conversion device 162 according to the present embodiment also includes the plurality of stacked portions Sp and the plurality of conductive layers (for example, the first to fourth conductive layer 18A to 18D). In the thermoelectric conversion device 162, a side wall insulating portion LP1 is provided, and, the insulating portion LP0 is not provided. Except for this, the thermoelectric conversion device 162 is the same as the thermoelectric conversion device 160, and thus a description thereof is omitted.

Along with the conductive layer and the base body 50s, which are described above, the side wall insulating portion LP1 seals a space in which the plurality of semiconductor portions are provided. An airtight space is formed. The space may be in a sub-atmospheric pressure state. The space may be in a state called a vacuum.

In the thermoelectric conversion device 160, the region between each of the plurality of first semiconductor portions 11P is a cavity. The region between each of the plurality of second semiconductor portions 12P is a cavity. These cavities are able to be reduced in pressure. Accordingly, for example, heat conduction can be suppressed between the conductive film 18A and the conductive film 18B. A temperature difference can be kept great. Also in the thermoelectric conversion device 161, a thermoelectric conversion device that can improve an output per unit area is provided.

The side wall insulating portion LP1, for example, contains silicon nitride. According to the present embodiment, a material of the side wall insulating portion LP1 is arbitrary so long as it is electrically insulating.

In this example, a sealing portion 18X is provided. In this example, an opening is provided in the fourth conductive layer 18D. The sealing portion 18X seals this opening. The sealing portion 18X, for example, contains resin.

An example of a method of manufacturing the thermoelectric conversion device 162 will be described below.

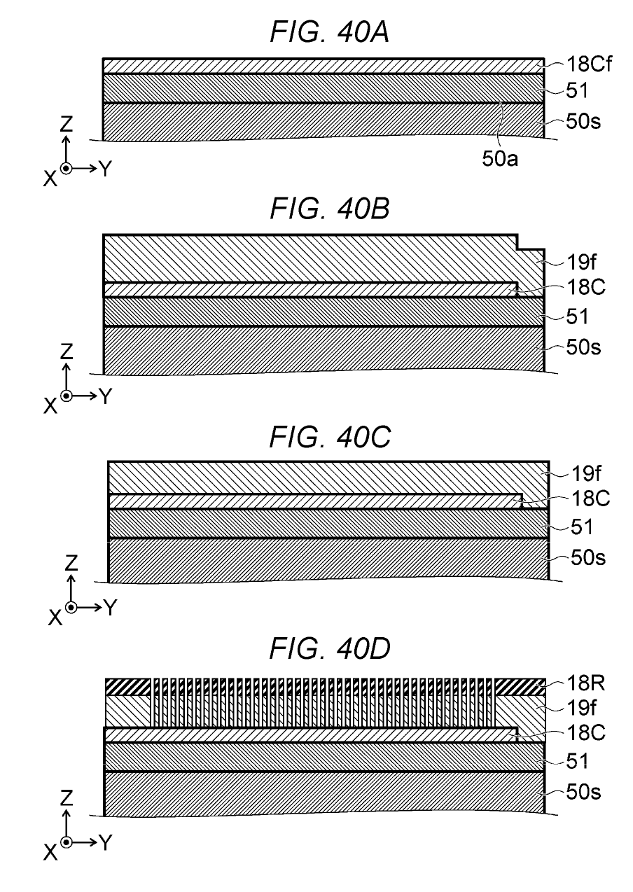

FIGS. 40A to 40D, FIGS. 41A to 41D, FIGS. 42A to 42D, and FIGS. 43A to 43D, FIGS. 44A and 44B, and FIG. 45 are schematic sectional views in the order of the processes, each illustrating a result of steps of the method of manufacturing the thermoelectric conversion device according to the sixth embodiment.

As illustrated in FIG. 40A, the conductive film 18Cf (for example, a tungsten film) that results in the third conductive layer 18C is formed on the insulating layer 51 (for example, a silicon nitride film) that is provided on the surface 50a of the base body 50s (for example, a silicon substrate).

As illustrated in FIG. 40B, one portion of the conductive film 18Cf is removed, and thus the third conductive layer 18C is formed. An insulating film 19f (for example, a silicon oxide film) is formed on the third conductive layer 18C.

As illustrated in FIG. 40C, the flattening process is performed.

As illustrated in FIG. 40D, the resist film 18R is formed. The resist film 18R has a plurality of openings. For formation of the openings, photolithography, EUV lithography, DSA, nanoimprint, electron beam patterning, or the like is used. Portions of the insulating film 19f are removed using the resist film 18R as a mask. Holes are formed in the insulating film 19f.

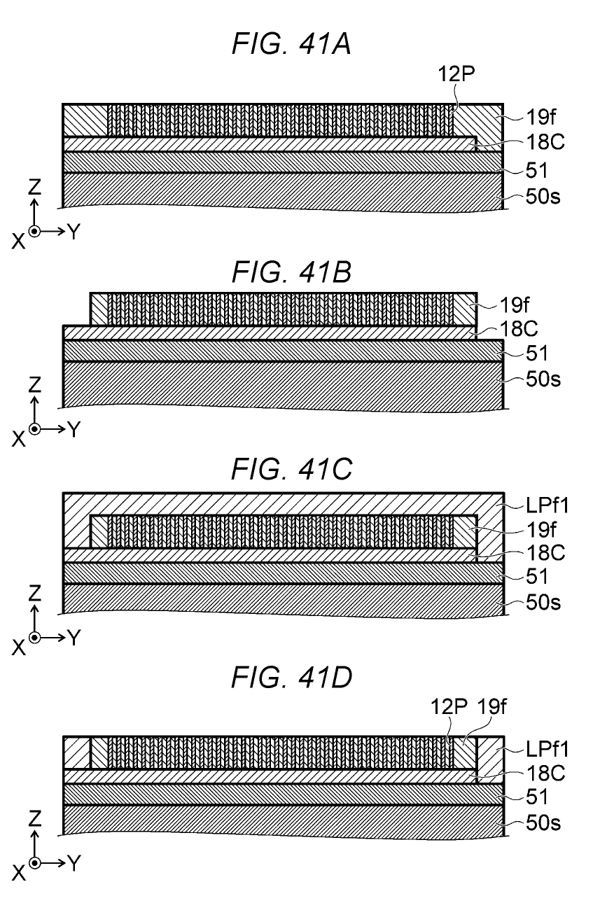

As illustrated in FIG. 41A, the semiconductor (for example, polysilicon) of the second conductivity type is buried into the hole in the insulating film 19f, and the fattening is performed. With the semiconductor, the second semiconductor portion 12P is formed.

As illustrated in FIG. 41B, one portion of an edge region of the insulating film 19f is removed.

As illustrated in FIG. 41C, an insulating film LPf1 that results in one portion of the side wall insulating portion LP1 is formed. The insulating film LPf1, for example, is a silicon oxide film.

As illustrated in FIG. 41D, the flattening is performed. For example, the second semiconductor portion 12P is exposed.

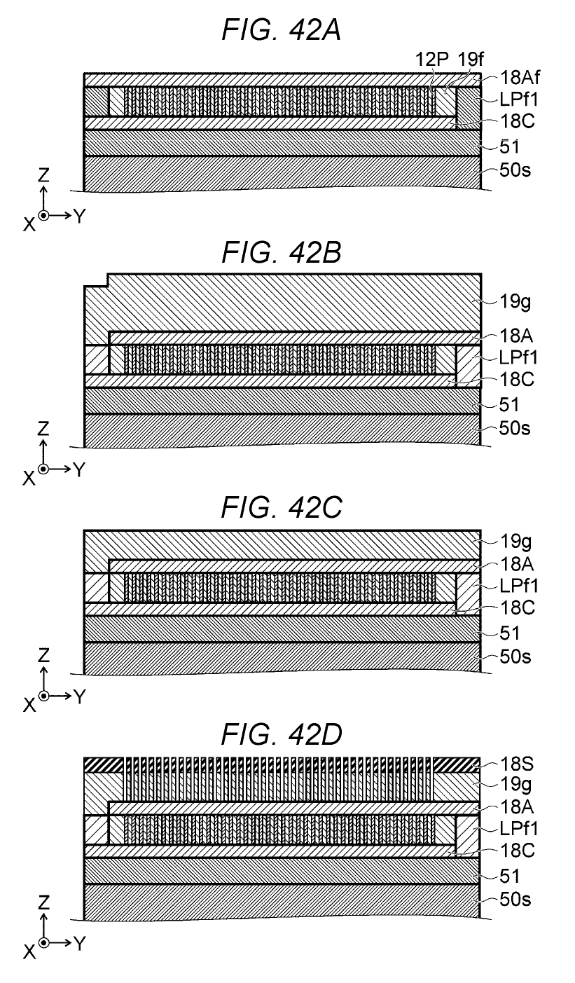

As illustrated in FIG. 42A, the conductive film 18Af (for example, a tungsten film) that results in the first conductive layer 18A is formed.

As illustrated in FIG. 42B, one portion of the conductive film 18Af is removed, and thus the first conductive layer 18A is formed. An insulating film 19g (for example, a silicon oxide film) is formed on the first conductive layer 18A.

As illustrated in FIG. 42C, the flattening process is performed.

As illustrated in FIG. 42D, the resist film 18S is formed. For the formation of the resist film 18S, for example, the method that is the same as the method of forming the resist film 18R is used. Portions of the insulating film 19g are removed using the resist film 18R as a mask. Holes are formed in the insulating film 19g.

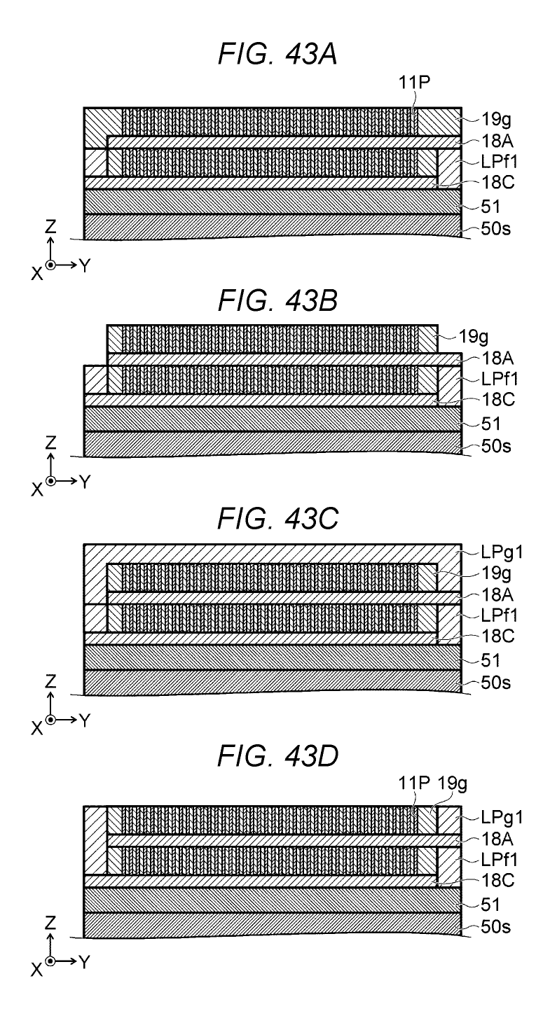

As illustrated in FIG. 43A, the semiconductor (for example, polysilicon) of the first conductivity type is buried into the hole in the insulating film 19g, and the fattening is performed. With the semiconductor, the first semiconductor portion 11P is formed.

As illustrated in FIG. 43B, one portion of an edge region of the insulating film 19g is removed.

As illustrated in FIG. 43C, an insulating film LPg1 that results in another portion of the side wall insulating portion LP1 is formed. The insulating film LPg1, for example, is a silicon oxide film.

As illustrated in FIG. 43D, the flattening is performed. For example, the second semiconductor portion 12P is exposed.

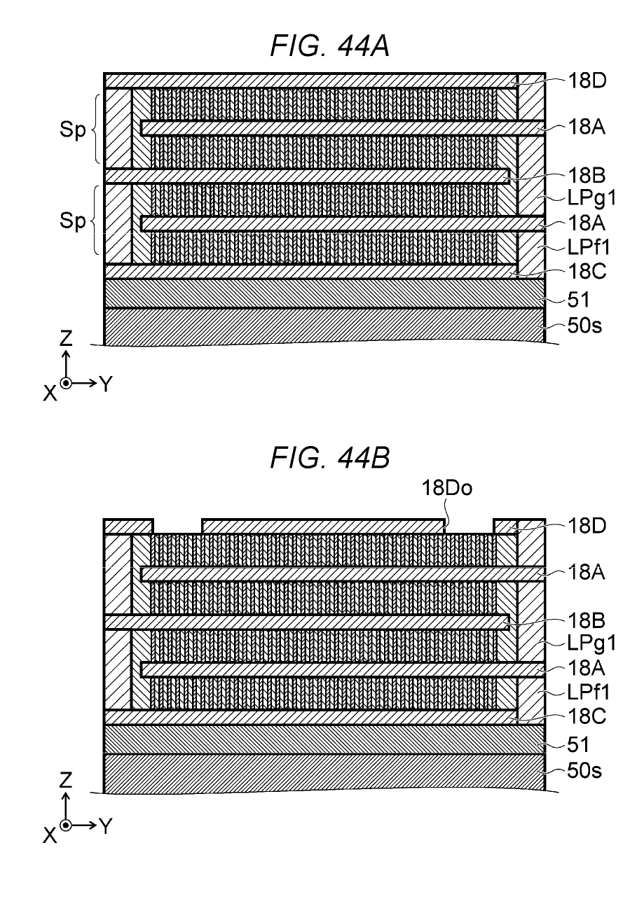

As illustrated in FIG. 44A, the processes described above are repeated. Accordingly, the plurality of stacked portions Sp, and the plurality of conductive layers (the first to fourth conductive layers 18A to 18D) are formed.

As illustrated in FIG. 44B, an opening 18Do is formed in the fourth conductive layer 18D.

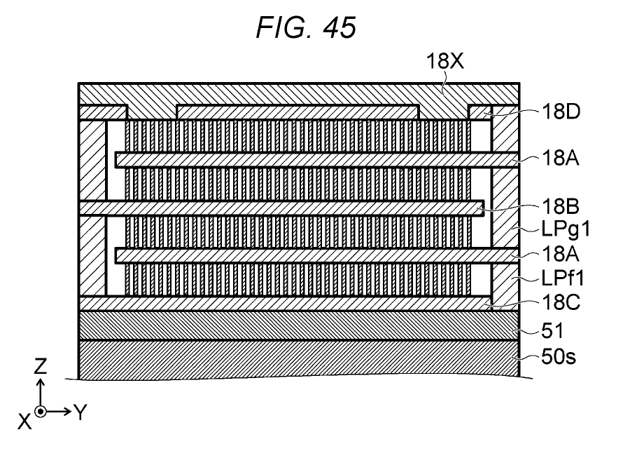

As illustrated in FIG. 45, the insulating films (the insulating film 19f, the insulating film 19g, and the like) are removed via the opening 18Do. The removal, for example, is performed by the wet etching or the like. Thereafter, the sealing portion 18X (for example, resin) is formed in such a manner that the sealing portion 18X is in a state in which the formed space is at a reduced pressure.

When the processing is performed as described, the thermoelectric conversion device 161 is manufactured.

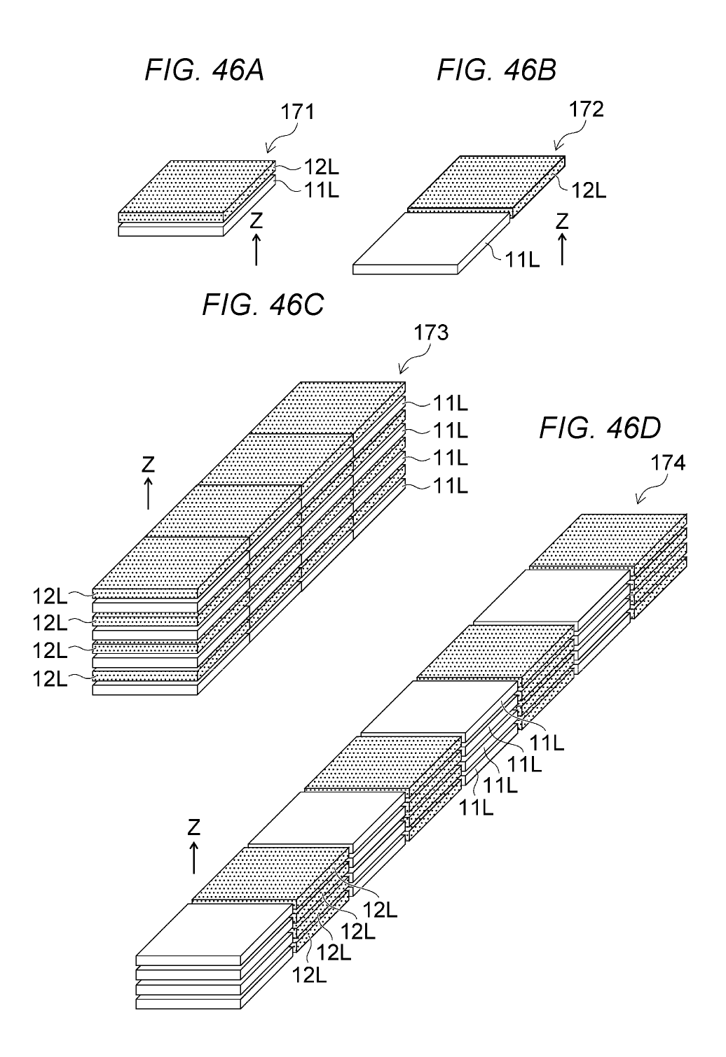

FIGS. 46A to 46D are schematic perspective diagrams illustrating the thermoelectric conversion device according to the embodiment.

These figures illustrate as a model a configuration of the thermoelectric conversion device according to the embodiment. In these figures, the holes (for example, the first to fourth holes HZ1 to HZ4 and the like), the plurality of stacked portions Sp, and the like are omitted. These figures illustrate a combination of arrangements of the semiconductor layers (or the semiconductor regions) in the thermoelectric conversion device.

As illustrated in FIG. 46A, in a thermoelectric conversion device 171, a first conductor region 11L and a second conductor region 12L are provided. The first conductor region 11L is a region in which the first semiconductor layer 11 is provided. The second conductor region 12L is a region in which the second semiconductor layer 12 is provided. In the thermoelectric conversion device 171, the first conductor region 11L and the second conductor region 12L are stacked in the Z-axis direction (the first direction).

As illustrated in FIG. 46B, in a thermoelectric conversion device 172, a direction for connecting the first conductor region 11L and the second conductor region 12L to each other intersects the Z-axis direction (the first direction). These regions are arranged on a plane (side by side).

A plurality of such regions may be provided, with each of the thermoelectric conversion devices 171 and 172 described above as a basic unit. When it comes to the basic unit, in a case where a unit voltage Ve is obtained, when N basic units are connected in series to each other, a voltage that is obtained is N×Ve. When it comes to the basic unit, in a case where a unit current Ie is obtained, when N basic units are connected in parallel to each other, a current is N×Ie.

As illustrated in FIG. 46C, in a thermoelectric conversion device 173, for example, four thermoelectric conversion devices 171 are stacked and thus are set to be one stacked unit. Four stacked units are further connected in parallel to each other.

As illustrated in FIG. 46D, in a thermoelectric conversion device 174, for example, four thermoelectric conversion devices 172 are stacked and thus are set to be one stacked unit. Four stacked units are further connected in parallel to each other.

According to the embodiment, a plurality of units may be connected in series and in parallel to each other. For example, one or several of the plurality of units may be connected in series to each other, and one other or several others of the plurality of units may be connected in parallel to each other. When the number of units that are connected in series to each other is increased, the voltage that is obtained increases. When the number of units that are connected in parallel to each other is increased, the current that is obtained increases.

Switching between connections of the plurality of units may be performed. For example, the in-parallel connection and the in-serial connection may replace each other by changing a connection state of the conductive portion that electrically connects the plurality of units to each other. An output in accordance with application is obtained.

According to the embodiments described above, it is easy to integrate thermoelectric conversion elements closely together with a compact construction. A thermoelectric conversion module can be provided at low cost.

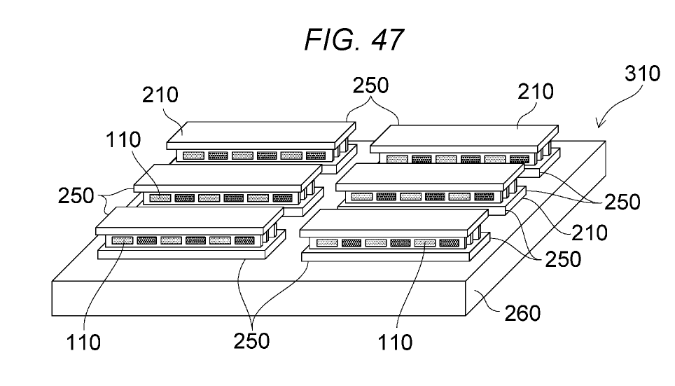

FIG. 47 is a schematic perspective diagram illustrating a thermoelectric conversion module according to the embodiment.

A thermoelectric conversion module 210 according to the embodiment includes a plurality of thermoelectric conversion devices according to the embodiment. In this example, the thermoelectric conversion device 110 is used as the plurality of thermoelectric conversion devices according to the embodiment. The thermoelectric conversion devices that are included in the thermoelectric conversion module 210 include one of the thermoelectric conversion devices according to the embodiments described above and a modification thereto. For example, the thermoelectric conversion module 210 may include thermoelectric conversion devices according to one of the first to sixth embodiments, and thermoelectric conversion devices according to another one of the first to sixth embodiments.

With a plurality of thermoelectric conversion modules 210, a thermoelectric conversion module system 310 is formed.

For example, the plurality of thermoelectric conversion modules 210 are provided on a base substrate 260. In one of the plurality of thermoelectric conversion modules 210, for example, a plurality of combinations of an n type semiconductor layer and a p type semiconductor layer are provided. The number of combinations, for example, is equal to or greater than 10 and is equal to smaller than 500. This number is an example, and thus is arbitrary. A length in one direction, of one of the plurality of thermoelectric conversion devices 110, for example, is 60 mm. A length in another direction, for example, is 25 mm, and the thickness is 2 mm. The lengths and the thickness are examples, and thus is arbitrary.

A plurality of thermoelectric conversion modules 210 are, for example, arranged in a matrix configuration along two directions on a base substrate 260. One of the plurality of thermoelectric conversion modules 210 and another one of the plurality of thermoelectric conversion modules 210, for example, are electrically connected in series or in parallel to each other. This connection, for example, is made with an interconnection 250. According to the embodiment, the connection state in which the plurality of thermoelectric conversion modules 210 is variable. For example, one of the plurality of thermoelectric conversion devices 110 and another one of the plurality of thermoelectric conversion devices 110 may be electrically connected in series or in parallel to each other.

For example, the base substrate 260 is the high temperature portion. The portion of the device that is positioned away from the base substrate 260 is the low temperature portion. For example, the base substrate 260 is attached to a wall, a pipe, or the like, which is at high temperature. Accordingly, a temperature difference occurs, and electric power is obtained.

According to the present embodiment, a desired voltage or current is obtained by connecting the plurality of thermoelectric conversion devices according to the embodiment to each other in series or in parallel. According to the present embodiment, a thermoelectric conversion module that can improve a power output per unit area can be provided.

According to the embodiments, the thermoelectric conversion device that can improve a power output per unit area can be provided.

It is noted that, in the present specification, a word “perpendicular” and a phrase “in parallel” are used not only in their respective strict senses, but are used also to mean, for example, that variations and the like are allowed in a manufacturing process. If an element is substantially perpendicular or substantially in parallel, this may be sufficient.

The embodiments described above refer to specific examples. However, the embodiments are not limited to these specific examples. For example, as long as a person of ordinary skill in the art can implement the exemplary embodiment in the same manner by making a suitable selection from a known range, specific configurations of each of the elements that are included in the thermoelectric conversion device, such as the semiconductor portion, the connection portion, the conductive layer, and the base body, fall within the scope of the exemplary embodiment.

Furthermore, any specific example that results from combining two or more of the elements within an available-technology range falls within the scope of the exemplary embodiment as long as the specific example constitutes the gist of the exemplary embodiment.

Additionally, all thermoelectric conversion devices that a person of ordinary skill in the art can implement by making a suitable design modification based on the thermoelectric conversion devices according to the exemplary embodiment, which are described above, also fall within the scope of the exemplary embodiment as long as the all thermoelectric conversion devices constitute the gist of the exemplary embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A thermoelectric conversion device, comprising:
a first stacked body comprising a plurality of first semiconductor layers of a first conductivity type, the first semiconductor layers spaced from each other in a first direction;
a second stacked body comprising a plurality of second semiconductor layers of a second conductivity type, the second semiconductor layers spaced from each other in the first direction; and
a first connection portion electrically connecting the first stacked body to the second stacked body,
wherein the first stacked body has a plurality of first openings that extend inwardly of the first stacked body in the first direction,
wherein a second direction from the first stacked body to the second stacked body intersects the first direction, and
wherein the second stacked body has a plurality of second openings extending inwardly of the second stacked body in the first direction.

2. The thermoelectric conversion device of claim 1, further comprising a first insulating layer interposed, in the first direction, between at least two first semiconductor layers.

3. The thermoelectric conversion device of claim 2, wherein the plurality of first openings are arranged in a hexagonal pattern when viewed from the first direction.

4. The thermoelectric conversion device of claim 1, further comprising a second connection portion electrically connected to at least one of the plurality of first semiconductor layers or to at least one of the plurality of second semiconductor layers.

5. The thermoelectric conversion device of claim 1, wherein the first stacked body further comprises a plurality of third semiconductor layers of the second conductivity type, the third semiconductor layers individually interposed between adjacent ones of the first semiconductor layers, and spaced therefrom.

6. The thermoelectric conversion device of claim 1, wherein the second stacked body further comprises a plurality of fourth semiconductor layers of the first conductivity type, the fourth semiconductor layers individually interposed between adjacent ones of the second semiconductor layers, and spaced therefrom.

7. The thermoelectric conversion device of claim 1, wherein the connection portion connects the first stacked body to the second stacked body electrically in series.

8. The thermoelectric conversion device of claim 1, wherein the connection portion connects the first stacked body to the second stacked body electrically in parallel.

9. A thermoelectric conversion device, comprising:
a first stacked body comprising a plurality of stacked portions comprising a first semiconductor layer of a first conductivity type and a second semiconductor layer of a second conductivity type, wherein the first and second semiconductor layers are spaced apart in a first direction; and
a first connection portion that electrically connects the first semiconductor layer of one of the plurality of stacked portions and the second semiconductor layer of one of the plurality of stacked portions to each other,
wherein the first stacked body has a plurality of first openings extending in the first stacked body in the first direction.

10. The thermoelectric conversion device of claim 9, wherein the first connection portion electrically connects a first semiconductor layer of one of the plurality of stacked portions and a second semiconductor layer of the same one of the plurality of stacked portions to each other.

11. The thermoelectric conversion device of claim 10, further comprising a second connection portion that electrically connects a first semiconductor layer of one of the plurality of stacked portions and a second semiconductor layer of a different one of the plurality of stacked portions to each other.

12. The thermoelectric conversion device of claim 9, wherein:
the first and second semiconductor layer of each stacked body are connected in series, and the first and second semiconductor layer of adjacent stacked bodies are connected in series, to form stacked body wherein the entire plurality of first and second semiconductor layers are connected in series;
a third connection portion is connected to the semiconductor layer at a first end of the series connected first and second semiconductor layers; and
a fourth connection portion is connected to the semiconductor layer at a second end of the series connected first and second semiconductor layers.

13. The thermoelectric conversion device of claim 9, further comprising:
a second stacked body comprising a plurality of stacked portions including a third semiconductor layer of a first conductivity type and a fourth semiconductor layer of a second conductivity type, wherein the third and fourth semiconductor layers are spaced apart in the first direction; and
a fifth connection portion that electrically connects at least one semiconductor layer of the first stacked body to at least semiconductor layer of the second stacked body,
wherein the second stacked body has a plurality of second openings extending in the second stacked body in the first direction.

14. A thermoelectric conversion device, comprising:
a first structured body that comprises a plurality of first stacked bodies;
a second structured body that comprises a plurality of second stacked bodies; and
a connection portion,
wherein each of the plurality of first stacked bodies comprises a plurality of first semiconductor layers of a first conductivity type spaced apart in a first direction, and at least one of the plurality of first semiconductor layers extends in a second direction that intersects the first direction,
wherein the plurality of first stacked bodies are spaced apart in a third direction that intersects the first direction and the second direction,
wherein each of the plurality of second stacked bodies comprises a plurality of second semiconductor layers of a second conductivity type spaced apart in the first direction, and at least one of the plurality of second semiconductor layers extends in the second direction,
wherein the plurality of second stacked bodies are spaced apart in the third direction,
wherein the direction from the first structured body to the second structured body is the third direction, and
wherein the connection portion electrically connects at least one of the plurality of first semiconductor layers and at least one of the plurality of second semiconductor layers to each other.

15. The thermoelectric conversion device of claim 14, wherein a first insulation layer extends between adjacent ones of the first semiconductor layers of the first stacked bodies in the first direction.

16. The thermoelectric conversion device of claim 14, wherein a gap extends between adjacent ones of the first semiconductor layers of the first stacked bodies in the third direction.

17. The thermoelectric conversion device of claim 14, wherein the connection portion electrically connects to a first end of the first semiconductor layers of the first stacked bodies.

18. The thermoelectric conversion device of claim 17, further comprising a terminal,
wherein the terminal electrically connects to a second end of the first semiconductor layers of the first stacked bodies, the second end distal from the first end of the first semiconductor layers.

19. The thermoelectric conversion device of claim 14, further comprising a substrate and a substrate insulating layer on a first surface of the substrate,
wherein the first and second stacked bodies are located on the substrate insulating layer.

20. The thermoelectric conversion device of claim 19, wherein the substrate has a recess extending inwardly of the first surface thereof.
